(19) United States
(12) Patent Application Publication
(10) Pub. No.: US 2024/0413615 A1
(43) Pub. Date: Dec. 12, 2024

(54) METHOD FOR MANUFACTURING QUANTUM CASCADE LASER DEVICE AND QUANTUM CASCADE LASER DEVICE

(71) Applicant: Mitsubishi Electric Corporation, Tokyo (JP)

(72) Inventor: Kimio SHIGIHARA, Tokyo (JP)

(73) Assignee: Mitsubishi Electric Corporation, Tokyo (JP)

(21) Appl. No.: 18/700,637

(22) PCT Filed: Jan. 24, 2022
(86) PCT No.: PCT/JP2022/002379

§ 371 Date: Apr. 11, 2024

(51) Int. Cl. H01S 5/34; H01S 5/343

(52) U.S. Cl. CPC H01S 5/3416; H01S 5/3402; H01S 5/34313; H01S 5/34346

(57) ABSTRACT

The present disclosure is a method for manufacturing a quantum cascade laser device comprising the steps of: virtually injecting electrons having an energy value from zero to an energy value of a conduction band edge of the well layer into a starting barrier layer; calculating energy dependence of transmissivity of the electrons transmitted from the terminal barrier layer; calculating energy values of local maximum values and the number of the local maximum values; calculating eigenvalues and eigenfunctions by solving a Schrödinger equation for each local maximum value by using each energy value of the local maximum values as an initial value; and setting a laser oscillation wavelength on the basis of the eigenvalues calculated for each of the local maximum values.

### TECHNICAL FIELD

The present disclosure relates to a method for manufacturing a quantum cascade laser device and a quantum cascade laser device.

### BACKGROUND ART

As described in Non-Patent Document 1, a quantum cascade laser (QCL) device has a layer structure in which stages each including an active region that emits mid-infrared light by optical transition between electron levels called subbands formed in a conduction band by a quantum confinement effect and an injector region that injects electrons into the active region are stacked in multiple stages.

Although the structure of the active region is important in determining an oscillation wavelength, there has been no guideline for designing the active region. That is, the structure of the active region of the quantum cascade laser device is determined so as to achieve a desired oscillation wavelength by a method of solving a Schrödinger equation to calculate energy levels (eigenvalues) and wave functions (eigenfunctions) by assuming a thickness of each well layer and a thickness of each barrier layer in advance, and repeatedly changing the thickness of each well layer and the thickness of each barrier layer until the transition wavelength between the upper level and the lower level approaches a desired value. Unfortunately, in such design method, it is unclear how many eigenvalues exist for the active region structure with each pre-assumed thickness of the well layer and each pre-assumed thickness of the barrier layer.

### CITATION LIST

### Non-Patent Document

Non-Patent Document 1: J. Kim, M. Lerttamrab, S. L. Chuang, C. Gmachl, D. L. Sivco, F. Capasso, and A. Y. Cho, “Theoretical and experimental study of optical gain and linewidth enhancement factor of type-I quantum-cascade lasers,” IEEE J. Quantum Electron., vol. 40, no. 12, pp. 1663 to 1674, 2004.

### SUMMARY OF THE INVENTION

### Problem to be Solved by the Invention

The conventional method for designing the active region of the quantum cascade laser device starts by solving the Schrödinger equation immediately using the pre-assumed thickness of the well layer and the pre-assumed thickness of a guide layer, which makes it difficult to set initial values in solving the Schrödinger equation. Furthermore, there is a problem that an energy difference between the upper level and the lower level corresponding to the transition wavelength cannot be known until the Schrödinger equation is solved.

In addition, when designing an active region of a quantum cascade laser device, the thickness of each well layer and the thickness of each barrier layer that compose of the active region can be set at any value, resulting in a large number of combinations, which makes the design process extremely complex until the structure of the active region is determined.

The present disclosure has been made to solve the above-described problems, and an object of the present disclosure is to provide a method for designing a quantum cascade laser device such that the number of well layers having a thickness to be determined and the number of barrier layers having a thickness to be determined can be reduced. Furthermore, it is an object of the present disclosure to provide a quantum cascade laser device designed by the method for designing a quantum cascade laser device.

### Means to Solve the Problem

A method for manufacturing a quantum cascade laser device according to the present disclosure having an active region with at least n layers of barrier layers and n layers of well layers alternately stacked, the method including the steps of: setting the number of the barrier layers and the number of the well layers to be at least n layers each; setting n pairs of stacked layers from a first pair of stacked layers to an n-th pair of stacked layers in the active region, each pair of stacked layers being a pair of the well layer and the barrier layer adjacent to the well layer; setting an electron-tunnelable thickness of a reference barrier layer as d_{b0} and a thickness of a reference well layer having a thickness thicker than the thickness of the reference barrier layer as d_{w0}, respectively; setting n coefficients from a coefficient a₁ to a coefficient an, each of the n coefficients being a positive real number; setting the thickness of the well layer and the thickness of the barrier layer of the k-th (1≤k≤n) pair of stacked layers as aₖ×d_{w0} and aₖ×d_{b0} respectively, with respect to the n pairs of stacked layers; virtually injecting electrons having an energy value from zero to an energy value of a conduction band edge of the well layer into a starting barrier layer, the starting barrier layer being a barrier layer provided on one end side and a terminal barrier layer being a barrier layer provided on the other end side; calculating energy dependence of transmissivity of the electrons transmitted from the terminal barrier layer; calculating energy values of local maximum values where the transmissivity of the electrons is locally maximized and the number of the local maximum values; calculating eigenvalues and eigenfunctions of a Schrödinger equation by solving the Schrödinger equation for each local maximum value by using each energy value of the local maximum values as an initial value; and setting a laser oscillation wavelength on the basis of the eigenvalues calculated for each of the local maximum values.

A quantum cascade laser device according to the present disclosure includes: a substrate; a first optical confinement layer formed above the substrate; a core region formed on the first optical confinement layer and including a plurality of stages; a second optical confinement layer formed on the core region; and a cladding layer formed on the second optical confinement layer, wherein the stage includes: an active region with at least n layers of barrier layers and n layers of well layers alternately stacked, a barrier layer provided on one end side of the active region being a starting barrier layer, and a barrier layer provided on the other end side of the active region being a terminal barrier layer; and an injector region that injects electrons into the active region, wherein energy dependence of transmissivity of the electrons transmitted from the terminal barrier layer is calculated by virtually injecting the electrons having an energy value from zero to an energy value of a conduction band edge of the well layer into the starting barrier layer; energy values of local maximum values where the transmissivity of the electrons is locally maximized, and the number of the local maximum values are calculated; eigenvalues and eigenfunctions of a Schrödinger equation are calculated by solving the Schrödinger equation for each local maximum value by using each energy value of the local maximum values as an initial value; and the quantum cascade laser device has a laser oscillation wavelength on the basis of the eigenvalue calculated for each of the local maximum values.

### Effect of the Invention

In the method for designing a quantum cascade laser device according to the present disclosure, since the number of eigenvalues in the structure of the active region and the approximate value of each eigenvalue are calculated in advance and the Schrödinger equation is solved using the approximate values as initial values, the Schrödinger equation can be solved more easily than in a case where there is no initial value. Therefore, the wave function corresponding to each eigenvalue can be obtained easily, as a result, the transition wavelength for the structure of the active region can be estimated easily, thus providing an effect of simplifying a design of an active region of a quantum cascade laser device.

In the quantum cascade laser device according to the present disclosure, the well layer and the barrier layer adjacent to the well layer are regarded as a pair of stacked layers, and the thickness of the well layer and the thickness of the barrier layer of the same pair of stacked layers are set by multiplying the thickness of the reference well layer and the thickness of the reference barrier layer by the same coefficient which is a positive real number, respectively. Therefore, the number of parameters for determining the layer thicknesses can be reduced, and thus the thicknesses of the well layers and the thicknesses of the barrier layers can be easily set, thus providing an effect that a quantum cascade laser device in which a laser oscillation wavelength is easily designed can be obtained.

### BRIEF DESCRIPTION OF THE DRAWINGS

FIG. 1 is an overview diagram showing a quantum cascade laser device according to Embodiment 1;

FIG. 2 is a schematic diagram showing a conduction band structure of a first stage of the quantum cascade laser device according to Embodiment 1 when an electric field is applied;

FIG. 3 is a schematic diagram showing the conduction band structure of an active region of the quantum cascade laser device according to Embodiment 1 when no bias is applied;

FIG. 4 is a schematic diagram showing transmission and reflection of an electron wave in an i-th layer and an adjacent i+1-th layer constituting the active region of the quantum cascade laser device according to Embodiment 1;

FIG. 5 shows electron energy dependence of an electron transmissivity T in the active region of the quantum cascade laser device according to Embodiment 1;

FIGS. 6A-6C show quantum levels (eigenvalues) and wave functions (eigenfunctions) obtained by solving a Schrödinger equation for the structure of the active region of the quantum cascade laser device according to Embodiment 1;

FIGS. 7A-7B show the quantum levels (eigenvalues) and the wave functions (eigenfunctions) obtained by solving the Schrödinger equation for the structure of the active region of the quantum cascade laser device according to Embodiment 1;

FIG. 8 is a schematic diagram showing a conduction band structure of an active region of a quantum cascade laser device according to Embodiment 2 when no bias is applied;

FIGS. 9A-9C show quantum levels (eigenvalues) and wave functions (eigenfunctions) obtained by solving the Schrödinger equation for an example of the structure of the active region of the quantum cascade laser device according to Embodiment 2;

FIGS. 10A-10C show the quantum levels (eigenvalues) and the wave functions (eigenfunctions) obtained by solving the Schrödinger equation for the structure of the example of the active region of the quantum cascade laser device according to Embodiment 2;

FIGS. 11A-11B show the quantum levels (eigenvalues) and the wave functions (eigenfunctions) obtained by solving the Schrödinger equation for the structure of the example of the active region of the quantum cascade laser device according to Embodiment 2;

FIGS. 12A-12C show the quantum levels (eigenvalues) and the wave functions (eigenfunctions) obtained by solving the Schrödinger equation for the structure of another example of the active region of the quantum cascade laser device according to Embodiment 2;

FIGS. 13A-13C show the quantum levels (eigenvalues) and the wave functions (eigenfunctions) obtained by solving the Schrödinger equation for the structure of another example of the active region of the quantum cascade laser device according to Embodiment 2;

FIGS. 14A-14B show the quantum levels (eigenvalues) and the wave functions (eigenfunctions) obtained by solving the Schrödinger equation for the structure of another example of the active region of the quantum cascade laser device according to Embodiment 2;

FIG. 15 is a schematic diagram showing a conduction band structure of an active region of a quantum cascade laser device according to Modification 1 of Embodiment 2 when no bias is applied;

FIGS. 16A-16C show quantum levels (eigenvalues) and wave functions (eigenfunctions) obtained by solving the Schrödinger equation for the structure of the active region of the quantum cascade laser device according to Modification 1 of Embodiment 2;

FIGS. 17A-17C show the quantum levels (eigenvalues) and the wave functions (eigenfunctions) obtained by solving the Schrödinger equation for the structure of the active region of the quantum cascade laser device according to Modification 1 of Embodiment 2;

FIGS. 18A-18C show quantum levels (eigenvalues) and wave functions (eigenfunctions) obtained by solving the Schrödinger equation for the structure of an active region of a quantum cascade laser device according to Modification 2 of Embodiment 2;

FIGS. 19A-19B show the quantum levels (eigenvalues) and the wave functions (eigenfunctions) obtained by solving the Schrödinger equation for the structure of the active region of the quantum cascade laser device according to Modification 2 of Embodiment 2;

FIG. 20 is a schematic diagram showing a conduction band structure of an active region of a quantum cascade laser device according to Embodiment 3 when no bias is applied;

FIG. 21 shows electron energy dependence of an electron transmissivity T in the active region of the quantum cascade laser device according to Embodiment 3;

FIGS. 22A-22C show quantum levels (eigenvalues) and wave functions (eigenfunctions) obtained by solving the Schrödinger equation for the structure of the active region of the quantum cascade laser device according to Embodiment 3;

FIGS. 23A-23C show the quantum levels (eigenvalues) and the wave functions (eigenfunctions) obtained by solving the Schrödinger equation for the structure of the active region of the quantum cascade laser device according to Embodiment 3;

FIG. 24 shows electron energy dependence of an electron transmissivity T in an active region of a quantum cascade laser device according to Modification 1 of Embodiment 3;

FIGS. 25A-25C show quantum levels (eigenvalues) and wave functions (eigenfunctions) obtained by solving the Schrödinger equation for the structure of the active region of the quantum cascade laser device according to Modification 1 of Embodiment 3;

FIGS. 26A-26C show the quantum levels (eigenvalues) and the wave functions (eigenfunctions) obtained by solving the Schrödinger equation for the structure of the active region of the quantum cascade laser device according to Modification 1 of Embodiment 3;

FIG. 27 is a schematic diagram showing a conduction band structure of an active region of a quantum cascade laser device according to Modification 2 of Embodiment 3 when no bias is applied;

FIG. 28 shows electron energy dependence of an electron transmissivity T in the active region of the quantum cascade laser device according to Modification 2 of Embodiment 3;

FIGS. 29A-29C show quantum levels (eigenvalues) and wave functions (eigenfunctions) obtained by solving the Schrödinger equation for the structure of the active region of the quantum cascade laser device according to Modification 2 of Embodiment 3;

FIGS. 30A-30C show the quantum levels (eigenvalues) and the wave functions (eigenfunctions) obtained by solving the Schrödinger equation for the structure of the active region of the quantum cascade laser device according to Modification 2 of Embodiment 3;

FIG. 31 is a schematic diagram showing a conduction band structure of an active region of a quantum cascade laser device according to Modification 3 of Embodiment 3 when no bias is applied;

FIG. 32 shows electron energy dependence of an electron transmissivity T in the active region of the quantum cascade laser device according to Modification 3 of Embodiment 3;

FIGS. 33A-33C show quantum levels (eigenvalues) and wave functions (eigenfunctions) obtained by solving the Schrödinger equation for the structure of the active region of the quantum cascade laser device according to Modification 3 of Embodiment 3; and

FIGS. 34A-34C show the quantum levels (eigenvalues) and the wave functions (eigenfunctions) obtained by solving the Schrödinger equation for the structure of the active region of the quantum cascade laser device according to Modification 3 of Embodiment 3.

### DESCRIPTION OF EMBODIMENTS

### Embodiment 1

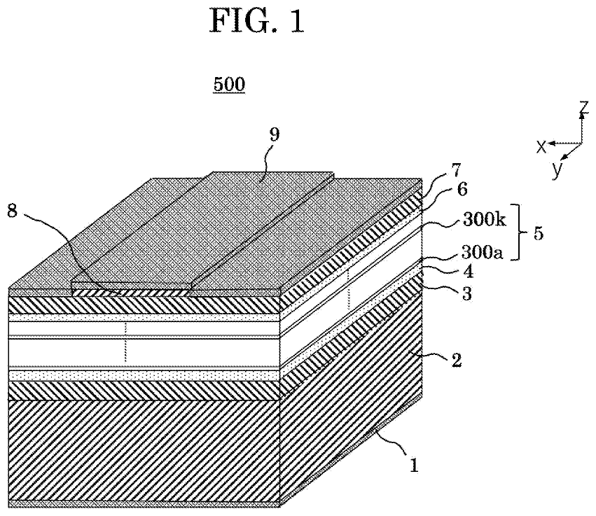

FIG. 1 is an overview diagram showing a quantum cascade laser device 500 according to Embodiment 1. The quantum cascade laser device 500 according to Embodiment 1 includes: a back-surface-side n-type electrode 1; an n-type InP substrate 2; an n-type InP buffer layer 3; an n-type GaInAs first optical confinement layer 4; a core region 5 composed of 30 to 40 stages; an n-type GaInAs second optical confinement layer 6; an n-type InP cladding layer 7; an n-type GaInAs contact layer 8; and a front-surface-side n-type electrode 9. An example in which the number of the stages 300 constituting the core region 5 is 30 to 40 is shown. However, the number of the stages 300 is not limited to one example, and the number of the stages 300 may be adjusted as appropriate depending on the desired laser characteristics.

When the quantum cascade laser device 500 according to Embodiment 1 is in operation, the back-surface-side n-type electrode 1 is biased negatively, and the front-surface-side n-type electrode 9 is biased positively. In operation, a voltage is applied between the back-surface-side n-type electrode 1 and the front-surface-side n-type electrode 9 to inject a current into the quantum cascade laser device 500, thereby causing laser oscillation.

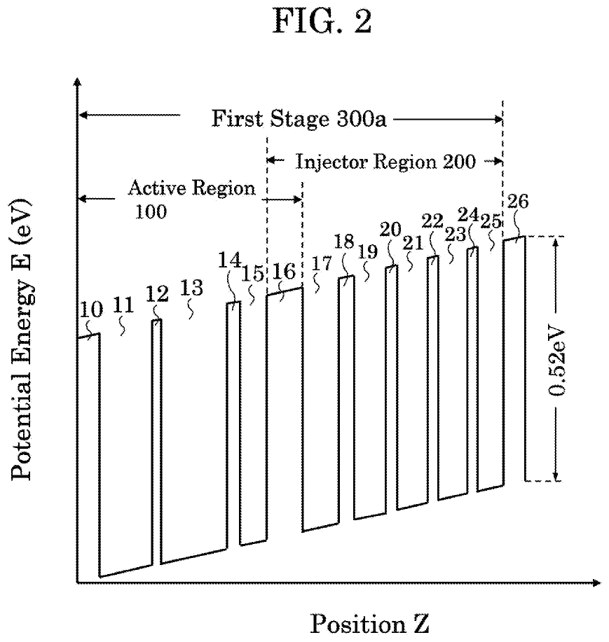

FIG. 2 is a schematic diagram of a conduction band structure showing the first stage 300a, which is one of the 30 to 40 stages 300 constituting the core region 5, when an electric field of 5.0×10⁶ V/m is applied to the quantum cascade laser device 500 according to Embodiment 1.

The stage 300 is composed of two regions, namely, an active region 100 that emits light mainly by transition of electrons between subbands (between quantum levels), and an injector region 200 that injects electrons mainly into the active region 100. The layers constituting the active region 100 are obtained on the basis of a method for designing a quantum cascade laser device according to Embodiment 1 described later. The core region 5 has a structure in which a plurality of stages 300 each having the active region 100 and the injector region 200 as one unit are stacked. In the above-described example, the core region 5 has a configuration in which 30 to 40 stages 300 are stacked. In FIG. 1, the first stage 300a and the k-th stage 300k are shown respectively from the side of the n-type GaInAs first optical confinement layer 4 in the core region 5. Hereinafter, the configurations of the active region 100 and the injector region 200 will be described by taking the first stage 300a as an example.

The active region 100 includes: an Al_{0.48}In_{0.52}As starting barrier layer 10 with a thickness of 2.4 nm and an Al composition ratio of 0.48; a Ga_{0.47}In_{0.53}As first well layer 11 with a thickness of 6.0 nm and a Ga composition ratio of 0.47; an Al_{0.4}In_{0.53}As first barrier layer 12 with a thickness of 0.9 nm and an Al composition ratio of 0.48; a Ga_{0.47}In_{0.53}As second well layer 13 with a thickness of 7.4 nm and a Ga composition ratio of 0.47; an Al_{0.4}In_{0.53}As second barrier layer 14 with a thickness of 1.5 nm and an Al composition ratio of 0.48; a Ga_{0.47}In_{0.53}As third well layer 15 with a thickness of 2.9 nm and a Ga composition ratio of 0.47; and an Al_{0.4}In_{0.53}As terminal barrier layer 16 with a thickness of 4.0 nm and an Al composition ratio of 0.48. Note that the Al_{0.4}In_{0.53}As terminal barrier layer 16 is also a part of the injector region 200 described later. This is because the Al_{0.4}In_{0.53}As terminal barrier layer 16 functions as the active region 100 and also functions as the injector region 200.

The injector region 200 includes: a Ga_{0.47}In_{0.53}As injector region first well layer 17 with a thickness of 4.1 nm and a Ga composition ratio of 0.47; an Al_{0.4}In_{0.53}As injector region first barrier layer 18 with a thickness of 1.7 nm and an Al composition ratio of 0.48; a Ga_{0.47}In_{0.53}As injector region second well layer 19 with a thickness of 3.7 nm and a Ga composition ratio of 0.47; an Al_{0.4}In_{0.53}As injector region second barrier layer 20 with a thickness of 1.2 nm and an Al composition ratio of 0.48; a Ga_{0.47}In_{0.53}As injector region third well layer 21 with a thickness of 3.4 nm and a Ga composition ratio of 0.47; an Al_{0.48}In_{0.53}As injector region third barrier layer 22 with a thickness of 1.1 nm and an Al composition ratio of 0.48; a Ga_{0.47}In_{0.53}As injector region fourth well layer 23 with a thickness of 3.4 nm and a Ga composition ratio of 0.47; an Al_{0.4}In_{0.53}As injector region fourth barrier layer 24 with a thickness of 1.1 nm and an Al composition ratio of 0.48; and a Ga_{0.47}In_{0.53}As injector region fifth well layer 25 with a thickness of 2.9 nm and a Ga composition ratio of 0.47. An Al_{0.4}In_{0.53}As starting barrier layer 26 with a thickness of 2.4 nm and an Al composition ratio of 0.48 in FIG. 2 is a part of the active region constituting the second stage.

The Al_{0.4}In_{0.53}As starting barrier layer 10, the Al_{0.4}In_{0.53}As terminal barrier layer 16, and the Al_{0.4}In_{0.53}As starting barrier layer 26 located at the boundary between the active region 100 and the injector region 200 may be allocated to each region by half of the layer thickness thereof, but in the present disclosure, such layers are treated as belonging to both regions.

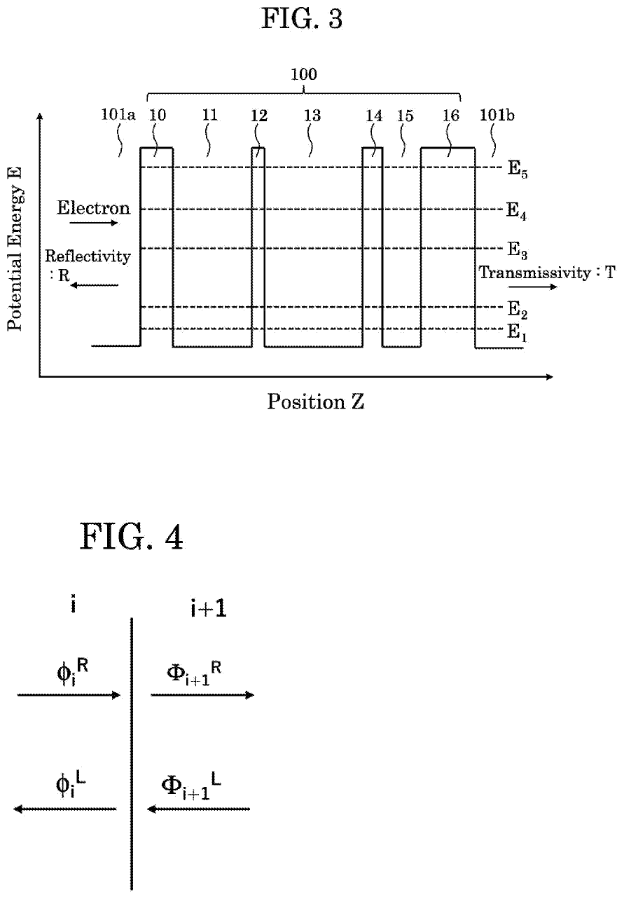

FIG. 3 shows a conduction band structure of the active region 100 constituting the quantum cascade laser device 500 according to Embodiment 1 when no bias is applied. Note that the configuration of the active region 100 constituting the quantum cascade laser device 500 described below is obtained on the basis of the method for designing a quantum cascade laser device according to Embodiment 1 described later.

In FIG. 3, the active region 100 of the quantum cascade laser device 500 includes: the Al_{0.48}In_{0.53}As starting barrier layer 10 with the thickness of 2.4 nm and the Al composition ratio of 0.48; the Ga_{0.47}In_{0.53}As first well layer 11 with the thickness of 6.0 nm and the Ga composition ratio of 0.47; the Al_{0.48}In_{0.53}As first barrier layer 12 with the thickness of 0.9 nm and the Al composition ratio of 0.48; the Ga_{0.47}In_{0.53}As second well layer 13 with the thickness of 7.4 nm and the Ga composition ratio of 0.47; the Al_{0.48}In_{0.53}As second barrier layer 14 with the thickness of 1.5 nm and the Al composition ratio of 0.48; the Ga_{0.47}In_{0.53}As third well layer 15 with the thickness of 2.9 nm and the Ga composition ratio of 0.47; and the Al_{0.48}In_{0.53}As terminal barrier layer 16 with the thickness of 4.0 nm and the Al composition ratio of 0.48. Note that the Al_{0.48}In_{0.53}As terminal barrier layer 16 is a terminal barrier layer in the active region 100.

Each barrier layer of the active region 100 is composed of an Al_{0.4}In_{0.53}As layer, which is a semiconductor layer of the same composition ratio, and each well layer of the active region 100 is composed of a Ga_{0.47}In_{0.53}As layer, which is a semiconductor layer of the same composition ratio. Hereinafter, each barrier layer may be collectively referred to as Al_{0.4}In_{0.53}As barrier layer, and each well layer may be collectively referred to as Ga_{0.47}In_{0.53}As well layer. Furthermore, the composition ratio of the semiconductor layer may be omitted, and for example, the Al_{0.4}In_{0.53}As first barrier layer 12 may be referred to as the AlInAs first barrier layer 12, and the Ga_{0.47}In_{0.53}As first well layer 11 may be referred to as the GaInAs first well layer 11.

For the convenience of calculation in the method for designing a quantum cascade laser device described later, a Ga_{0.47}In_{0.53}As dummy well layer 101a and a Ga_{0.47}In_{0.53}As dummy well layer 101b, each having a Ga composition ratio of 0.47, are virtually provided on both end sides of the active region 100. An energy difference V₀ between the Ga_{0.47}In_{0.53}As well layer and the Al_{0.4}In_{0.53}As barrier layer is 0.52 eV. The energy difference V₀ corresponds to an energy value from zero to an energy value of a conduction band edge of the well layer. Note that as shown in the overview diagram of FIG. 1, the active region 100 is assumed to be stacked on the InP substrate 2, but is not limited to the InP substrate 2.

FIG. 4 is a schematic view showing transmission and reflection of electron waves between the i-th layer and the adjacent i+1-th layer. In the i-th layer, the rightward electron wave is φᵢ^{R} and the leftward electron wave is φᵢ^{L}. In the i+1-th layer, the rightward electron wave is φ₁₊₁^{R}, and the leftward electron wave is φ_{I+1}^{L}.

When the above-described i-th layer is a well layer and the i+1-th layer is a barrier layer, the electron wave in the i-th layer can be expressed by the following Equation (1) with the electron wave in the i+1-th layer.

$$\begin{matrix}[ Equation 1 ] & \\ [ \begin{matrix}Φ \text{?} \\ Φ \text{?}\end{matrix} ] = \frac{1}{2 {k}_{i}} [ \begin{matrix}( {k}_{i} + {i}_{{𝒳}_{i + 1}} ) & {e}^{( - {ik}_{i} + {𝒳}_{i + 1} )} {\sum }^{i} {d}_{j} & ( {k}_{i} - {i}_{{𝒳}_{i + 1}} ) & {e}^{( - {ik}_{i} + {𝒳}_{i + 1} )} {\sum }^{i} {d}_{j} \\ ( {k}_{i} - {i}_{{𝒳}_{i + 1}} ) & {e}^{( {ik}_{i} - {𝒳}_{i + 1} )} {\sum }^{i} {d}_{j} & ( {k}_{i} + {i}_{{𝒳}_{i + 1}} ) & \end{matrix} ] [ \begin{matrix}{Φ}_{i + 2}^{R} \\ {Φ}_{i + 1}^{L}\end{matrix} ] & ( 1 )\end{matrix}$$

$$\text{?} \text{indicates text missing or illegible when filed}$$

In the Equation (1), dᵢ is a thickness of the i-th layer. Furthermore, kᵢ and xᵢ in the Equation (1) can be expressed by the following Equation (2).

$$\begin{matrix}[ Equation 2 ] & \\ \begin{matrix}{k}_{i} = \frac{\sqrt{2 m \text{?} E}}{ℏ} \\ {𝒳}_{i} = \frac{\sqrt{2 m \text{?} ( E - {V}_{0} )}}{ℏ}\end{matrix} & ( 2 )\end{matrix}$$

$$\text{?} \text{indicates text missing or illegible when filed}$$

m*ᵢ: Effective mass of electron of i-th layer
h: Planck constant

Similarly, when the i-th layer is a barrier layer and the i+1-th layer is a well layer, the electron wave in the i-th layer can be expressed by the following Equation (3) with the electron wave in the i+1-th layer.

$$\begin{matrix}[ Equation 3 ] & \\ [ \begin{matrix}Φ \text{?} \\ Φ \text{?}\end{matrix} ] = \frac{1}{{{2}_{𝒳}}_{i}} [ \begin{matrix}( {𝒳}_{i} - {ik}_{i + 1} ) & {e}^{( {𝒳}_{i} + {ik}_{i + 1} )} {\sum }^{i} {d}_{j} & ( {𝒳}_{i} + {ik}_{i + 1} ) & {e}^{( {𝒳}_{i} - {k}_{i + 1} )} {\sum }^{i} {d}_{j} \\ ( {𝒳}_{i} + {ik}_{i + 1} ) & {e}^{( {𝒳}_{i} + {ik}_{i + 1} )} {\sum }^{i} {d}_{j} & ( {𝒳}_{i} - {ik}_{i + 1} ) & {e}^{( - {k}_{i} - {ik}_{i + 1} )} {\sum }^{i} {d}_{j}\end{matrix} ] [ \begin{matrix}{Φ}_{i + 1}^{R} \\ {Φ}_{i + 1}^{L}\end{matrix} ] & ( 3 )\end{matrix}$$

$$\text{?} \text{indicates text missing or illegible when filed}$$

By sequentially repeating the calculation of the above Equation (3) for each layer constituting the active region 100, the electronic wave incident from the Ga_{0.47}In_{0.53}As dummy well layer 101a that is assumed to be the zeroth layer of each layer including the active region 100 can be expressed by a following Equation (4) by the electronic wave emitted to the Ga_{0.47}In_{0.53}As dummy well layer 101b that is assumed to be the eighth layer of each layer including the active region 100.

$$\begin{matrix}[ Equation 4 ] & \\ [ \begin{matrix}{Φ}_{0}^{R} \\ {Φ}_{0}^{L}\end{matrix} ] = [ \begin{matrix}{M}_{11} & {M}_{12} \\ {M}_{21} & {M}_{22}\end{matrix} ] [ \begin{matrix}{Φ}_{8}^{R} \\ {Φ}_{8}^{L}\end{matrix} ] & ( 4 )\end{matrix}$$

When electrons with energy E (0≤E≤V₀) are incident on the AlInAs starting barrier layer 10, the electron reflectivity from the AlInAs starting barrier layer 10 is denoted by R, and the electron transmissivity from the AlInAs terminal barrier layer 16 is denoted by T. The electron transmissivity T can be expressed by the following Equation (5).

$$\begin{matrix}[ Equation 5 ] & \\ T = {\vert \frac{1}{{M}_{11}} \vert}^{2} & ( 5 )\end{matrix}$$

When the energy of electrons incident on the AlInAs starting barrier layer 10 is changed from zero to the energy V₀ at the conduction band edge of the well layer and the electron transmissivity T from the AlInAs terminal barrier layer 16 is calculated, the electron transmissivity T is high at the energy at which the quantum levels exist, and the electron transmissivity T is low at the energy other than the quantum levels. That is, in FIG. 3, E₁, E₂, E₃, E₄, and E₅, which represent energy values indicated by dotted lines in FIG. 3, are the respective quantum levels of the active region 100. At each quantum level, the electron transmissivity T is estimated to be higher. Hereinafter, E₁, E₂, E₃, E₄, and E₅ are referred to as a first quantum level E₁, a second quantum level E₂, a third quantum level E₃, a fourth quantum level E₄, a fifth quantum level E₅, or the like, respectively.

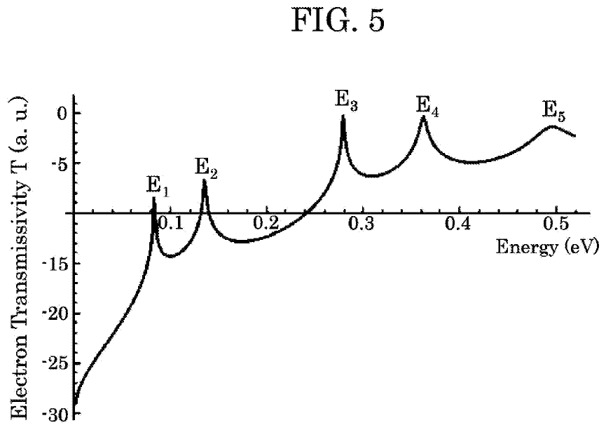

FIG. 5 is a graph showing the electron energy dependence of the electron transmissivity T in the structure of the active region 100 shown in FIG. 3. The vertical axis of FIG. 5 represents the electron transmissivity T in natural logarithm. The horizontal axis of FIG. 5 represents the energy value of electrons, and the unit of the energy value is electron volt (eV). As shown in FIG. 5, it is found that there are five local maximum values E₁, E₂, E₃, E₄, and E₅ in the electron transmissivity T. Hereinafter, the maximum value which exists locally is referred to as a local maximum value. For the structure of the active region 100 shown in FIG. 3, a Schrödinger equation shown in the following Equation (6) is actually to be solved.

$$\begin{matrix}[ Equation 6 ] & \\ - \frac{{ℏ}^{2}}{2} \frac{d}{dz} [ \frac{1}{{m}^{*} ( z )} \frac{d \text{?} ( z )}{dz} ] + V ( z ) \text{?} ( z ) = {E}_{n} \text{?} ( z ) & ( 6 )\end{matrix}$$

$$\text{?} \text{indicates text missing or illegible when filed}$$

In the Equation (6), m*(z) represents an effective mass distribution, V(z) represents a potential energy distribution, Eₙ represents the quantum level (eigenvalue), and uₙ(z) represents the wave function (eigenfunction), respectively.

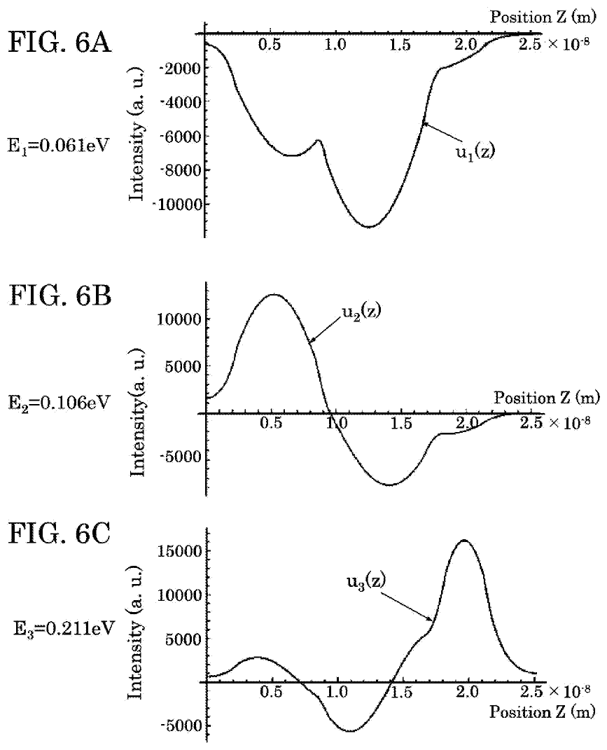

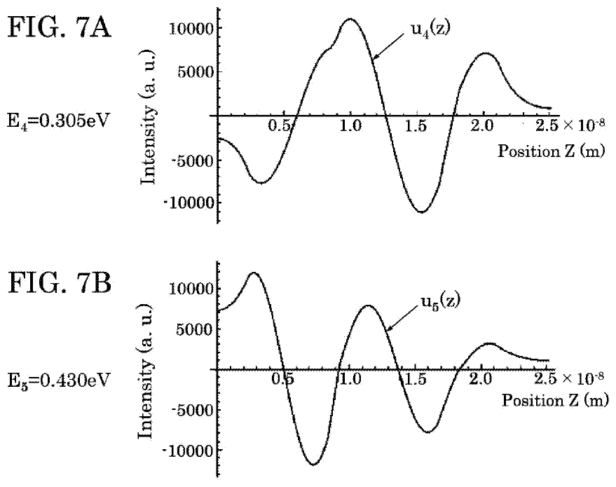

FIGS. 6A-6C and 7A-7B show quantum levels (eigenvalues) and wave functions (eigenfunctions) obtained by solving the Schrödinger equation for the structure of the active region 100 shown in FIG. 3. In each of FIGS. 6A-6C and 7A-7B, the vertical axis represents an intensity of the wave function, and the horizontal axis represents a position Z. The unit of the position Z is meter (m). Note that the wave function is normalized as in the following Equation (7). Thus, |uₙ(z)|² represents the probability of the existence of the electron at the position Z.

$$\begin{matrix}[ Equation 7 ] & \\ \int \vert \text{?} ( z ) {\vert}^{2} dz = 1 & ( 7 )\end{matrix}$$

$$\text{?} \text{indicates text missing or illegible when filed}$$

FIG. 6A represents the wave function of the first quantum level E₁(E₁=0.061 eV), FIG. 6B represents the wave function of the second quantum level E₂ (E₂=0.106 eV), and FIG. 6C represents the wave function of the third quantum level E₃ (E₃=0.211 eV), respectively. FIG. 7A represents the wave function of the fourth quantum level E₄ (E₄=0.305 eV), and FIG. 7B represents the wave function of the fifth quantum level E₅ (E₅=0.430 eV), respectively.

If the transition for laser oscillation occurs between the third quantum level E₃ (E₃=0.211 eV) and the second quantum level E₂ (E₂=0.106 eV), the energy difference between the third quantum level E₃ and the second quantum level E₂ is 0.105 eV, and thus wavelength at which laser oscillation occurs is 11.7 μm.

By calculating the number of eigenvalues and the approximate value of each eigenvalue in the structure of the active region in advance with Equations (1) through (5), and then the approximate values are applied as initial values, the Schrödinger equation represented by Equation (6) can be easily solved, and thus the wave function corresponding to each eigenvalue can be obtained.

In the method for designing a quantum cascade laser device according to Embodiment 1, the Schrödinger equation is solved in a non-bias state in which no electric field is applied. However, in a bias state in which an electric field is applied, the Schrödinger equation may be solved by using the eigenvalues (quantum levels) calculated in the non-bias state as initial values. That is, a following design method may be used. The design method is to calculate the energy at which the electron transmissivity T has a local maximum in the non-bias state, then solve the Schrödinger equation in the non-bias state by using the energy at which the local maximum occurs as the initial value, and then calculate the eigenvalues of the energy by solving the Schrödinger equation in the bias state by using the eigenvalues in the non-bias state as initial values.

### Effects of Embodiment 1

As described above, the method for designing a quantum cascade laser device according to Embodiment 1, since the number of eigenvalues in the structure of the active region and the approximate value of each eigenvalue are calculated in advance and the Schrödinger equation is solved using the approximate values as initial values, the Schrödinger equation can be solved more easily than in a case where there is no initial value and thus the wave function corresponding to each eigenvalue can be obtained easily. As a result, the transition wavelength for the structure of the active region can be estimated easily, thus providing an effect of simplifying a design of an active region of a quantum cascade laser device.

### Embodiment 2

The active region of a typical quantum cascade laser device has a structure in which the composition ratio of well layers and the composition ratio of barrier layers are constant, respectively, and the thicknesses of each well layer and each barrier layer are varied. On the other hand, the quantum cascade laser device according to Embodiment 2 has a thickness d_{b0} of a reference barrier layer, which is a layer thickness through which electrons can tunnel, and a thickness d_{w0} of a reference well layer, which is thicker than the reference barrier layer, and also regard the well layer and the barrier layer adjacent at the upper or lower of the well layer, which are constituting the active region 110, as a pair of stacked layers, and then the thicknesses of the well layer and the barrier layer of the same pair of stacked layers are set to be the same positive real number times the thickness d_{w0} of the reference well layer and the thickness d_{b0} of the reference barrier layer multiplied by the same coefficient that is the positive real number, respectively.

For example, in a case where the thickness of the well layer P is dₚ, and the thickness of the barrier layer Q, which is adjacent to the well layer P and constitutes the pair of stacked layers together with the well layer P, is d_{q}, and then the well layer P and the barrier layer Q constituting the pair of stacked layers are set to r times the thickness using the coefficient r with respect to the thicknesses of the reference well layer and the reference barrier layer described above, the thickness dₚ of the well layer P is set to r×d_{w0}, and the thickness d_{q} of the barrier layer Q is set to r×d_{b0}, respectively.

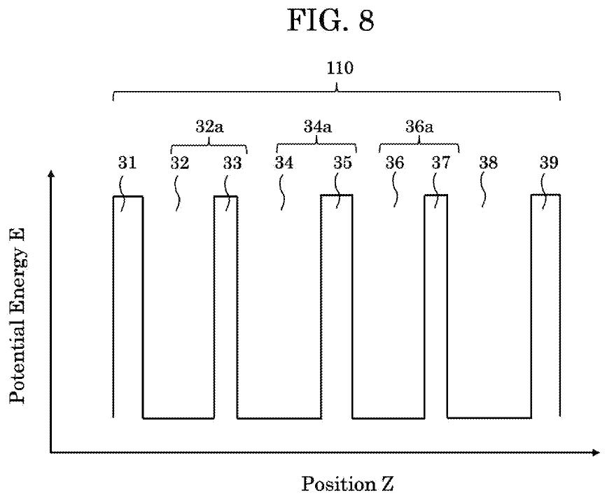

FIG. 8 is a diagram showing a conduction band structure of an active region 110 of the quantum cascade laser device according to Embodiment 2 when no bias is applied. The active region 110 includes: an Al_{0.48}In_{0.52}As starting barrier layer 31 with a thickness of 2.0 nm and an Al composition ratio of 0.48; a Ga_{0.47}In_{0.53}As first well layer 32 with a thickness of d₁ (d₁=a₁×d_{w0}) and a Ga composition ratio of 0.47; an Al_{0.48}In_{0.53}As first barrier layer 33 with a thickness of d₂ (d₂=a₁×d_{b0}) and an Al composition ratio of 0.48; a Ga_{0.47}In_{0.53}As second well layer 34 with a thickness of d₃ (d₃=a₂×d_{w0}) and a Ga composition ratio of 0.47; an Al_{0.48}In_{0.53}As second barrier layer 35 with a thickness of d₄ (d₄=a₂×d_{b0}) and an Al composition ratio of 0.48; a Ga_{0.47}In_{0.53}As third well layer 36 with a thickness of d₅ (d₅=a₃×d_{w0}) and a Ga composition ratio of 0.47; an Al_{0.48}In_{0.53}As third barrier layer 37 with a thickness of d₆ (d₆=a₃×d_{b0}) and an Al composition ratio of 0.48; a Ga_{0.47}In_{0.53}As fourth well layer 38 with a thickness of d₇ (d₇=a₄×d_{w0}) and a Ga composition ratio of 0.47; and an Al_{0.48}In_{0.53}As terminal barrier layer 39 with a thickness of 2.0 nm and an Al composition ratio of 0.48.

In the above description, the coefficients a₁, a₂, a₃, and a₄ are constants formed of positive real numbers. The Ga_{0.47}In_{0.53}As first well layer 32 and the Al_{0.48}In_{0.53}As first barrier layer 33 constitute a first pair of stacked layers 32a, the Ga_{0.47}In_{0.53}As second well layer 34 and the Al_{0.48}In_{0.53}As second barrier layer 35 constitute a second pair of stacked layers 34a, and the Ga_{0.47}In_{0.53}As third well layer 36 and the Al_{0.48}In_{0.53}As third barrier layer 37 constitute a third pair of stacked layers 36a.

Since a laser oscillation wavelength is assumed to be about 9 μm in the active region 110, the thickness d_{w0} of the reference well layer and the thickness d_{b0} of the reference barrier layer are set to 8.0 nm and 1.0 nm, respectively. The thicknesses of the AlInAs starting barrier layer 31 and the AlInAs terminal barrier layer 39 are both 2.0 nm. However, the thicknesses of the AlInAs starting barrier layer and the AlInAs terminal barrier layer are not limited to such layer thickness, as long as the layer thicknesses thereof are sufficient to allow electron tunneling.

In a case where a₁=1.0, a_{2=1.0}, a_{3=1.0}, and a₄=1.0, which are examples of the thicknesses of the layers constituting the active region 110, that is, in a case where the thickness of each well layers is equal to the thickness of the reference well layer and the thickness of each barrier layer except for the AlInAs starting barrier layer 31 and the AlInAs terminal barrier layer 39 is equal to the thickness of the reference barrier layer, by applying the method for designing a quantum cascade laser device according to Embodiment 1, each quantum level (each eigenvalue) and each wave function (each eigenfunction) are calculated by solving the Schrödinger equation represented by Equation (6).

According to the above-described setting, the thicknesses of the layers constituting the active region 110 are as follows: the thickness d₁ of the GaInAs first well layer 32 is 8.0 nm; the thickness d₂ of the AlInAs first barrier layer 33 is 1.0 nm; the thickness d₃ of the GaInAs second well layer 34 is 8.0 nm; the thickness d₄ of the AlInAs second barrier layer 35 is 1.0 nm; the thickness d₅ of the GaInAs third well layer 36 is 8.0 nm; the thickness d₆ of the AlInAs third barrier layer 37 is 1.0 nm; and the thickness d₇ of the GaInAs fourth well layer 38 is 8.0 nm.

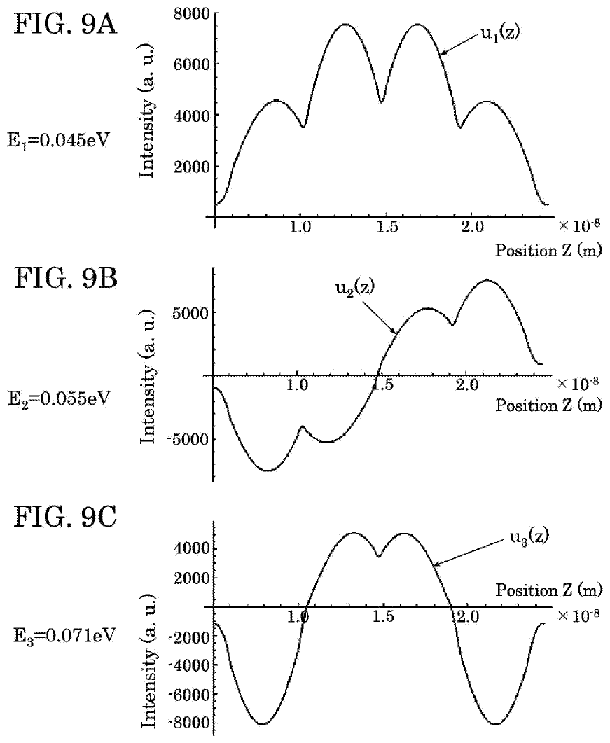

Each quantum level (each eigenvalue) and each wave function (each eigenfunction) of the active region 110 are shown in FIGS. 9A-9C, 10A-10C, and 11A-11B, respectively.

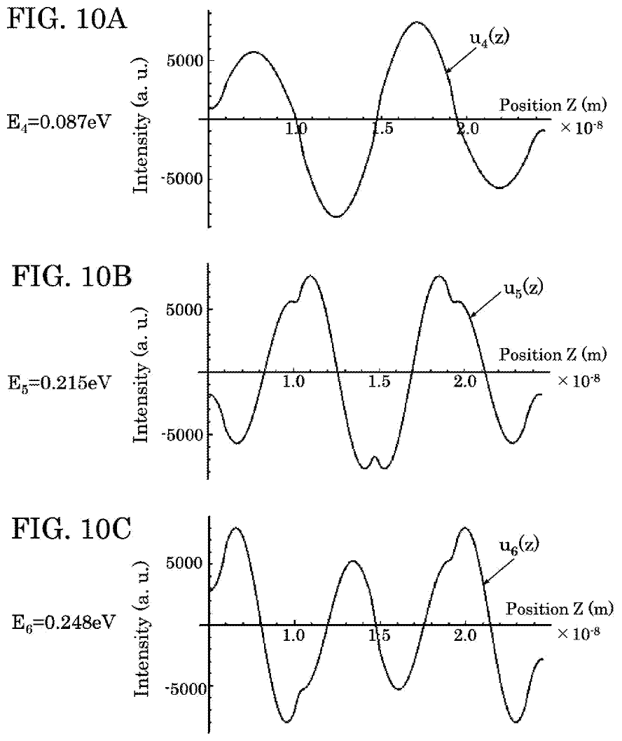

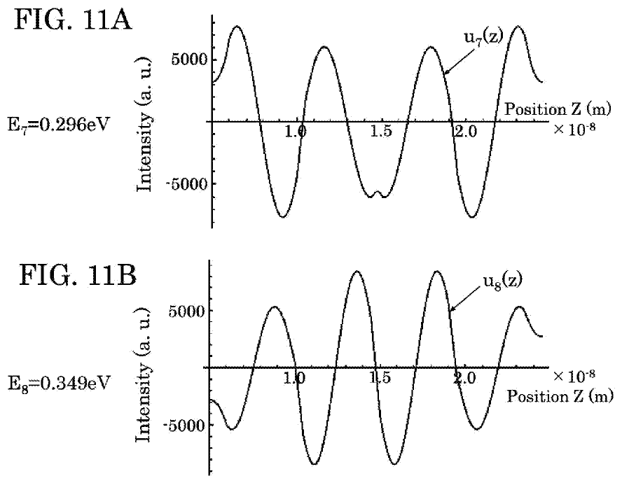

FIG. 9A represents the wave function of the first quantum level E₁(E₁=0.045 eV), FIG. 9B represents the wave function of the second quantum level E₂ (E₂=0.055 eV), and FIG. 9C represents the wave function of the third quantum level E₃ (E₃=0.071 eV), respectively. FIG. 10A represents the wave function of the fourth quantum level E₄ (E₄=0.087 eV), FIG. 10B represents the wave function of the fifth quantum level E₅(E₅=0.215 eV), and FIG. 10C represents the wave function of the sixth quantum level E₆ (E₆=0.248 eV), respectively. FIG. 11A represents the wave function of the seventh quantum level E₇ (E₇=0.296 eV), and FIG. 11B represents the wave function of the eighth quantum level E₅(E₅=0.349 eV), respectively.

If the transition for laser oscillation occurs between the fifth quantum level E₅(E₅=0.215 eV) and the fourth quantum level E₄ (E₄=0.087 eV), the energy difference between the fifth quantum level E₅ and the fourth quantum level E₄ is 0.128 eV, and thus the transition wavelength is 9.7 μm.

The coefficients a₁, a₂, a₃, and a₄, which are positive real numbers, can take arbitrary values. Next, in a case where a₁=1.0, a₂=0.9, a₃=0.9, and a₄=0.9, that is, in a case where the thickness d₁ of the GaInAs first well layer 32 is the same thickness of the reference well layer and the thickness d₂ of the GaInAs first barrier layer 33 is the same thickness of the reference barrier layer, and the thickness of each well layer except for the GaInAs first well layer 32 is the thickness of the reference well layer multiplied by 0.9, and each barrier layer except for the AlInAs starting barrier layer 31, the GaInAs first barrier layer 33 and the AlInAs terminal barrier layer 39 is the thickness of the reference barrier layer multiplied by 0.9, by applying the method for designing a quantum cascade laser device according to Embodiment 1, each quantum level (each eigenvalue) and each wave functions (each eigenfunction) are calculated by solving the Schrödinger equation represented by Equation (6).

According to the above-described setting, the thicknesses of the layers constituting the active region 110 are as follows: the thickness d₁ of the GaInAs first well layer 32 is 8.0 nm; the thickness d₂ of the AlInAs first barrier layer 33 is 1.0 nm; the thickness d₃ of the GaInAs second well layer 34 is 7.2 nm; the thickness d₄ of the AlInAs second barrier layer 35 is 0.9 nm; the thickness d₅ of the GaInAs third well layer 36 is 7.2 nm; the thickness d₆ of the AlInAs third barrier layer 37 is 0.9 nm; and the thickness d₇ of the GaInAs fourth well layer 38 is 7.2 nm.

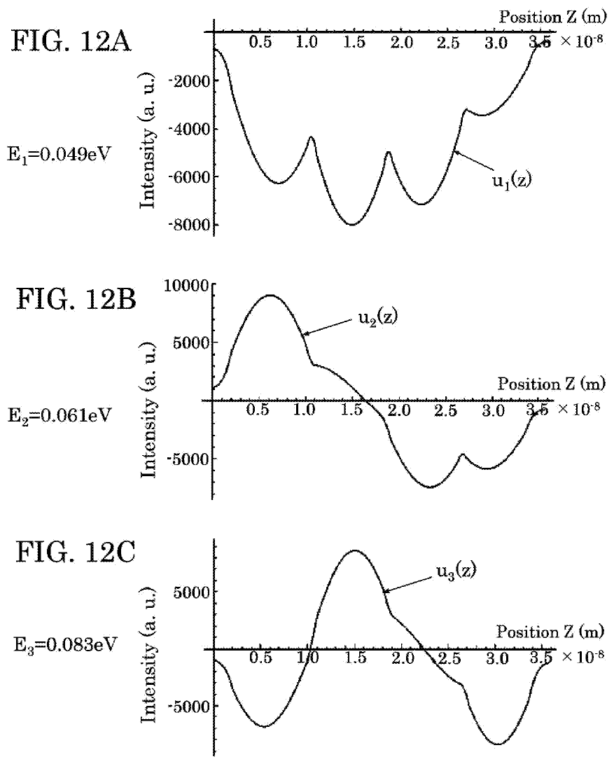

Each quantum level (each eigenvalue) and each wave function (each eigenfunction) of the active region 110 are shown in FIGS. 12A-12C, 13A-13C, and 14A-14B, respectively.

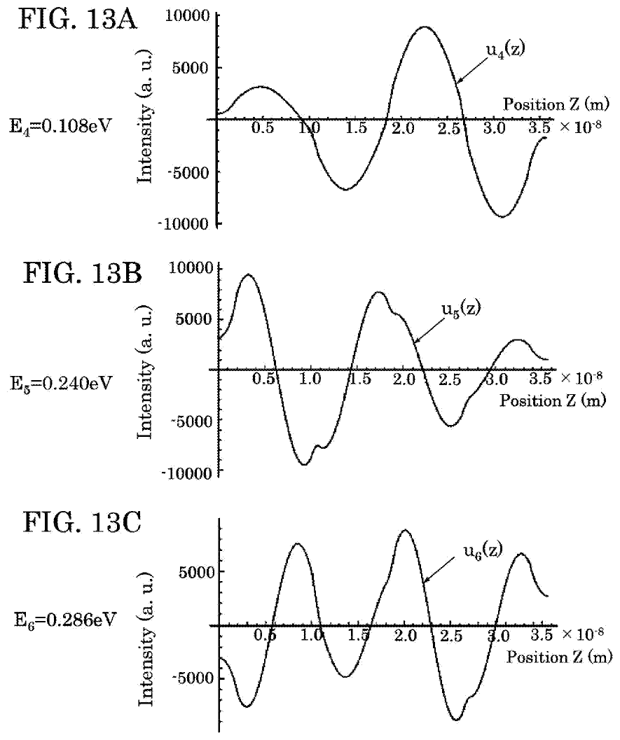

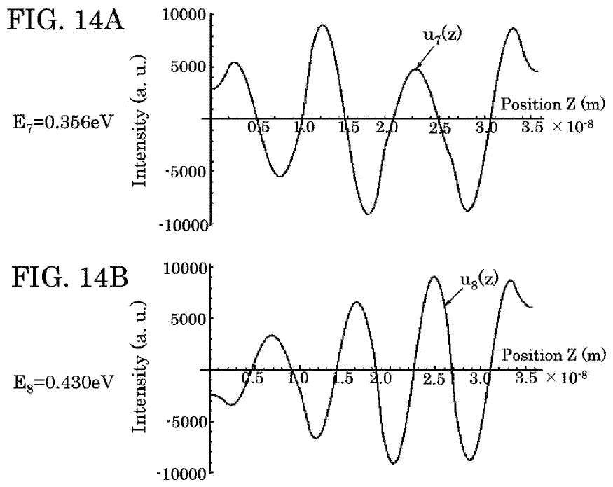

FIG. 12A represents the wave function of the first quantum level E₁ (E₁=0.049 eV), FIG. 12B represents the wave function of the second quantum level E₂ (E₂=0.061 eV), and FIG. 12C represents the wave function of the third quantum level E₃ (E₃=0.083 eV), respectively. FIG. 13A represents the wave function of the fourth quantum level E₄ (E₄=0.108 eV), FIG. 13B represents the wave function of the fifth quantum level E₅(E₅=0.240 eV), and FIG. 13C represents the wave function of the sixth quantum level E₆ (E₆=0.286 eV), respectively. FIG. 14A represents the wave function of the seventh quantum level E₇ (E₇=0.356 eV), and FIG. 14B represents the wave function of the eighth quantum level E₈ (E₈=0.430 eV), respectively.

If the transition for laser oscillation occurs between the fifth quantum level E₅(E₅=0.240 eV) and the fourth quantum level E₄ (E₄=0.108 eV), the energy difference between the fifth quantum level E₅ and the fourth quantum level E₄ is 0.132 eV, and thus the transition wavelength is 9.4 μm.

### Modification 1 of Embodiment 2

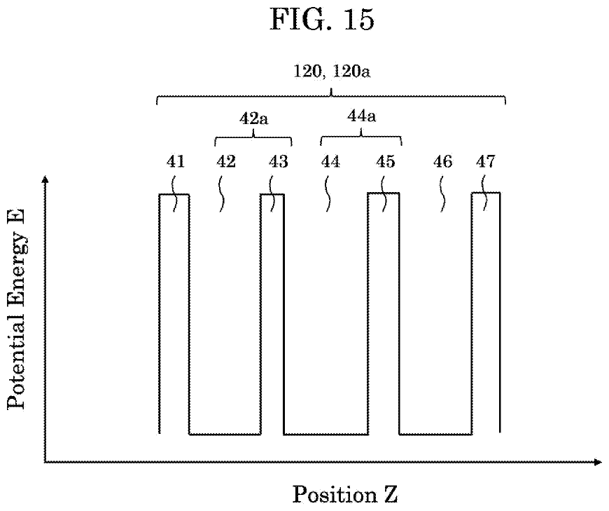

In a quantum cascade laser device according to Modification 1 of Embodiment 2, the number of the well layers constituting the active region 120 is three. FIG. 15 is a schematic diagram showing a conduction band structure in a case where the active region 120 of the quantum cascade laser device according to Modification 1 of Embodiment 2 includes three well layers when no bias is applied.

The active region 120 includes: an Al_{0.48}In_{0.52}As starting barrier layer 41 with a thickness of 2.0 nm and an Al composition ratio of 0.48; a Ga_{0.47}In_{0.53}As first well layer 42 with a thickness of d₁ (d₁=a₁×d_{w0}) and a Ga composition ratio of 0.47; an Al_{0.48}In_{0.53}As first barrier layer 43 with a thickness of d₂ (d₂=a₁×d_{b0}) and an Al composition ratio of 0.48; a Ga_{0.47}In_{0.53}As second well layer 44 with a thickness of d₃ (d₃=a₂×d_{w0}) and a Ga composition ratio of 0.47; an Al_{0.48}In_{0.53}As second barrier layer 45 with a thickness of d₄ (d₄=a₂×d_{b0}) and an Al composition ratio of 0.48; a Ga_{0.47}In_{0.53}As third well layer 46 with a thickness of d₅ (d₅=a₃×d_{w0}) and a Ga composition ratio of 0.47; and an Al_{0.48}In_{0.53}As terminal barrier layer 47 with a thickness of 2.0 nm and an Al composition ratio of 0.48.

The Ga_{0.47}In_{0.53}As first well layer 42 and the Al_{0.4}In_{0.53}As first barrier layer 43 constitute a first pair of stacked layers 42a, and the Ga_{0.47}In_{0.53}As second well layer 44 and the Al_{0.4}In_{0.53}As second barrier layer 45 constitute a second pair of stacked layers 44a, respectively.

Since a laser oscillation wavelength is assumed to be about 6 μm in the active region 120, the thickness d_{w0} of the reference well layer and the thickness d_{b0} of the reference barrier layer are set to 6.0 nm and 1.0 nm, respectively. The thicknesses of the AlInAs starting barrier layer 41 and the AlInAs terminal barrier layer 47 are set to both 2.0 nm. However, the thicknesses of the AlInAs starting barrier layer and the AlInAs terminal barrier layer are not limited to such layer thickness, as long as the layer thickness thereof is sufficient to allow electron tunneling.

In a case where a₁=1.0, a_{2=1.0}, and a₃=1.0, which are examples of the thicknesses of the layers constituting the active region 120, that is, in a case where the thickness of each well layer is equal to the thickness of the reference well layer and the thickness of each barrier layer except for the AlInAs starting barrier layer 41 and the AlInAs terminal barrier layer 47 is equal to the thickness of the reference barrier layer, by applying the method for designing a quantum cascade laser device according to Embodiment 1, each quantum level (each eigenvalue) and each wave function (each eigenfunction) are calculated by solving the Schrödinger equation represented by Equation (6).

According to the above-described setting, the thicknesses of the layers constituting the active region 120 are as follows: the thickness d₁ of the GaInAs first well layer 42 is 6.0 nm; the thickness d₂ of the AlInAs first barrier layer 43 is 1.0 nm; the thickness d₃ of the GaInAs second well layer 44 is 6.0 nm; the thickness d₄ of the AlInAs second barrier layer 45 is 1.0 nm; and the thickness d₅ of the GaInAs third well layer 46 is 6.0 nm.

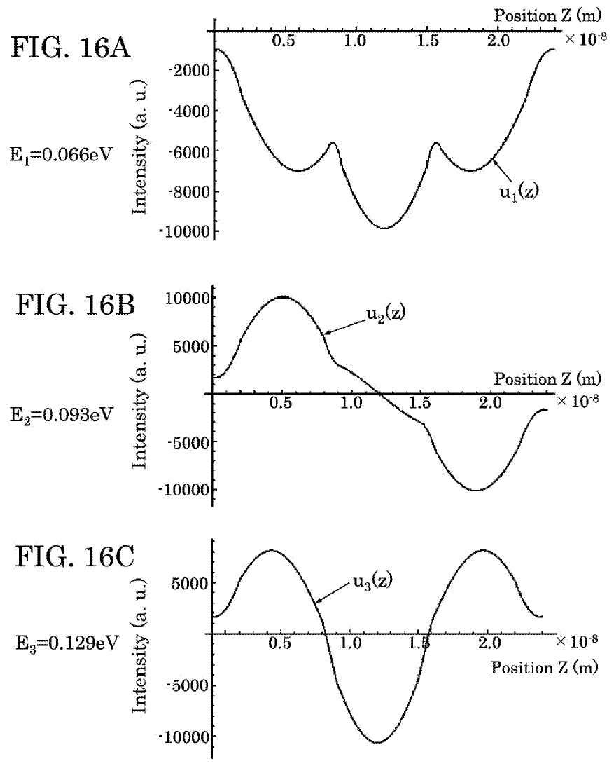

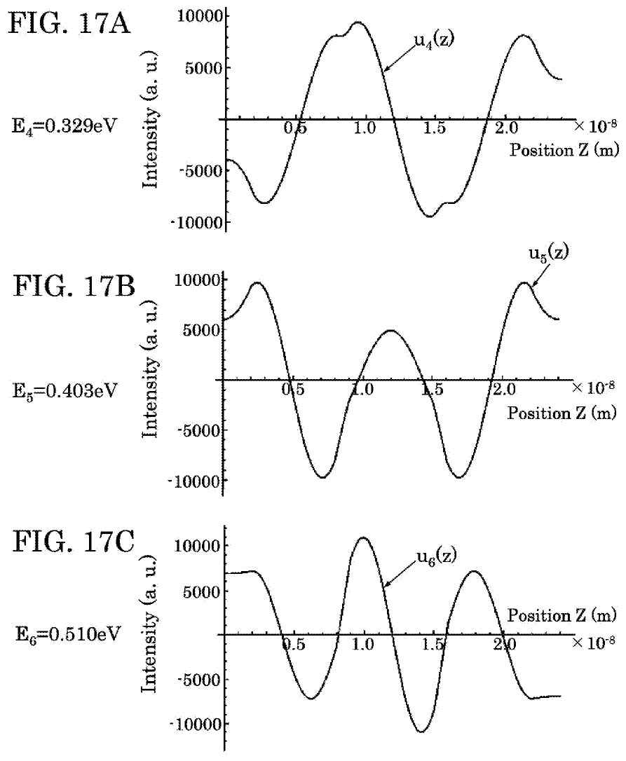

Each quantum level (each eigenvalue) and each wave function (each eigenfunction) of the active region 120 are shown in FIGS. 16A-16C and 17A-17C, respectively.

FIG. 16A represents the wave function of the first quantum level E₁ (E₁=0.066 eV), FIG. 16B represents the wave function of the second quantum level E₂ (E₂=0.093 eV), and FIG. 16C represents the wave function of the third quantum level E₃ (E_{3=0.129} eV), respectively. FIG. 17A represents the wave function of the fourth quantum level E₄ (E₄=0.329 eV), FIG. 17B represents the wave function of the fifth quantum level E₅(E₅=0.403 eV), and FIG. 17C represents the wave function of the sixth quantum level E₆ (E₆=0.510 eV), respectively.

If the transition for laser oscillation occurs between the fourth quantum level E₄ (E₄=0.329 eV) and the third quantum level E₃ (E₃=0.129 eV), the energy difference between the fourth quantum level E₄ and the third quantum level E₃ is 0.200 eV, and thus the transition wavelength is 6.2 μm.

### Modification 2 of Embodiment 2

The coefficients a₁, a₂, and a₃, which are positive real numbers, can take arbitrary values. The active region 120a of the quantum cascade laser device according to Modification 2 of Embodiment 2 has a₁=1.0, a_{2=0.8}, and a₃=0.8. That is, in configuration of the active region 120a, the thickness d₁ of the GaInAs first well layer 42 is the same thickness of the reference well layer and the thickness d₂ of the GaInAs first barrier layer 43 is the same thickness of the reference barrier layer, and the thickness of each well layer except for the GaInAs first well layer 42 is the thickness of the reference well layer multiplied by 0.8, and the thickness of each barrier layer except for the AlInAs starting barrier layer 41, the GaInAs first barrier layer 43 and the AlInAs terminal barrier layer 47 is the thickness of the reference barrier layer multiplied by 0.8.

According to the above-described setting, the thicknesses of the layers constituting the active region 120a are as follows: the thickness d₁ of the GaInAs first well layer 42 is 6.0 nm; the thickness d₂ of the AlInAs first barrier layer 43 is 1.0 nm; the thickness d₃ of the GaInAs second well layer 44 is 4.8 nm; the thickness d₄ of the AlInAs second barrier layer 45 is 0.8 nm; and the thickness d₅ of the GaInAs third well layer 46 is 4.8 nm.

For the active region 120a of the quantum cascade laser device according to Modification 2 of Embodiment 2, by applying the method for designing a quantum cascade laser device according to Embodiment 1, each quantum level (each eigenvalue) and each wave function (each eigenfunction) are calculated by solving the Schrödinger equation represented by Equation (6).

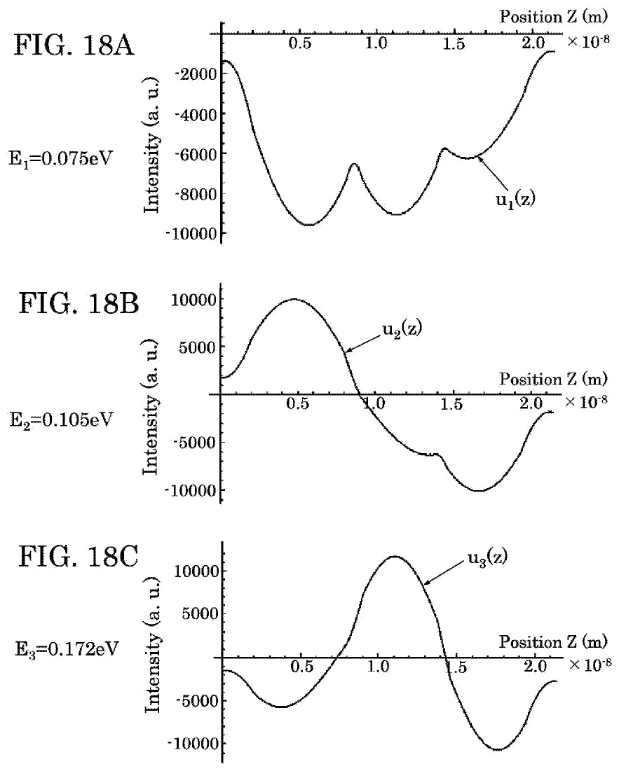

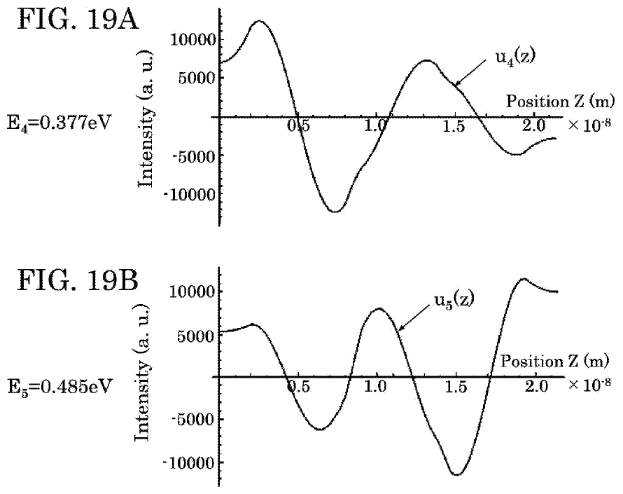

Each quantum level (each eigenvalue) and each wave function (each eigenfunction) of the active region 120a are shown in FIGS. 18A-18C and 19A-19B, respectively.

FIG. 18A represents the wave function of the first quantum level E₁(E₁=0.075 eV), FIG. 18B represents the wave function of the second quantum level E₂ (E₂=0.105 eV), and FIG. 18C represents the wave function of the third quantum level E₃ (E₃=0.172 eV), respectively. FIG. 19A represents the wave function of the fourth quantum level E₄ (E₄=0.377 eV), and FIG. 19B represents the wave function of the fifth quantum level E₅(E₅=0.485 eV).

If the transition for laser oscillation occurs between the fourth quantum level E₄ (E₄=0.377 eV) and the third quantum level E₃ (E₃=0.172 eV), the energy difference between the fourth quantum level E₄ and the third quantum level E₃ is 0.205 eV, and thus the transition wavelength is 6.1 μm.

Since the well layer and the barrier layer adjacent to the well layer are regarded as a pair of stacked layers, and the thicknesses of the well layer and the barrier layer of the same pair of stacked layers are set by multiplying the thickness of the reference well layer and the thickness of the reference barrier layer by the same coefficient, which is a positive real number, respectively, the number of parameters for determining the layer thicknesses can be reduced, and thus the thicknesses of the well layers and the barrier layers can be easily set. Furthermore, the transition wavelength can be easily changed by changing the thickness of the reference well layer. In short, the design for an active region of a quantum cascade laser device can be simplified compared to conventional methods for designing.

Furthermore, by applying the method for designing a quantum cascade laser device according to Embodiment 1 with respect to the configuration of the respective thicknesses of the well layers and the barrier layers constituting the active region 120a described above, the design for an active region of a quantum cascade laser device is further facilitated.

In Embodiment 2, the cases of three and four well layers constituting the active region are shown, but the number of well layers is not limited to such cases, and the structure of the active region can be easily designed even in the case of other numbers of well layers.

### Effects of Embodiment 2

As described above, the method for designing a quantum cascade laser device according to Embodiment 2, the well layer and the barrier layer adjacent to the well layer are regarded as a pair of stacked layers, and the thickness of the well layer and the thickness of the barrier layer of the same pair of stacked layers are set by multiplying the thickness of the reference well layer and the thickness of the reference barrier layer by the same coefficient that is a positive real number, respectively. Therefore, the number of parameters for determining the layer thicknesses can be reduced, and thus the thicknesses of the well layers and the thicknesses of the barrier layers can be easily set, thus providing an effect of obtaining a quantum cascade laser device in which a laser oscillation wavelength is easily designed.

Furthermore, since the thickness of each layer constituting the active region of the quantum cascade laser device according to Embodiment 2 is determined by applying the method for designing a quantum cascade laser device according to Embodiment 1, it is possible to easily estimate the transition wavelength with respect to the structure of the active region, thus providing an effect that it is possible to easily design a quantum cascade laser device.

### Embodiment 3

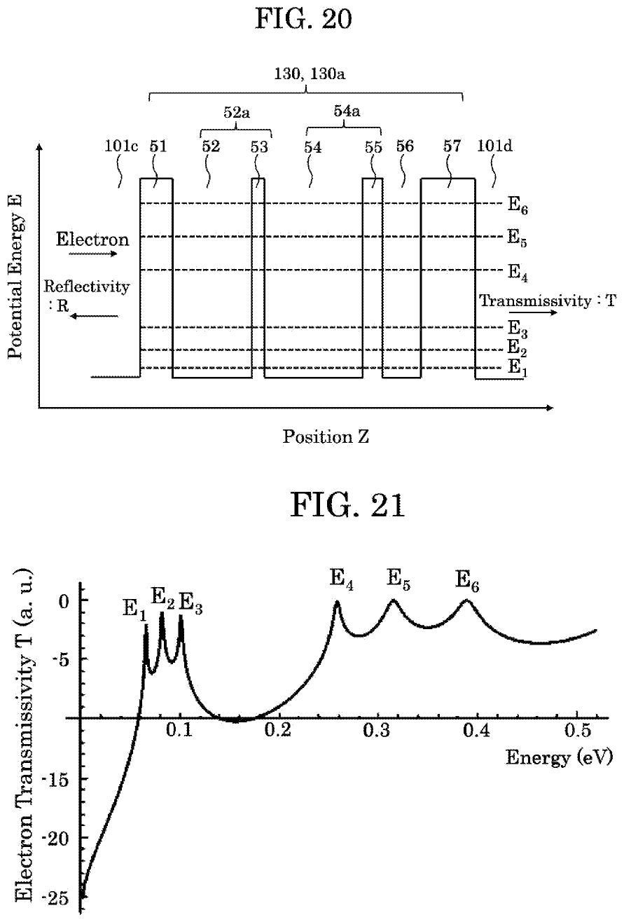

FIG. 20 is a diagram showing a conduction band structure of an active region 130 of the quantum cascade laser device according to Embodiment 2 when no bias is applied. The active region 130 includes: an Al_{0.4}In_{0.52}As starting barrier layer 51 with a thickness of 2.0 nm and an Al composition ratio of 0.48; a Ga_{0.47}In_{0.53}As first well layer 52 with a thickness of d₁ (d₁=a₁×d_{w0}) and a Ga composition ratio of 0.47; an Al_{0.4}In_{0.53}As first barrier layer 53 with a thickness of d₂ (d₂=a₁×d_{b0}) and an Al composition ratio of 0.48; a Ga_{0.47}In_{0.53}As second well layer 54 with a thickness of d₃ (d₃=a₂×d_{w0}) and a Ga composition ratio of 0.47; an Al_{0.4}In_{0.53}As second barrier layer 55 with a thickness of d₄ (d₄=a₂×d_{b0}) and an Al composition ratio of 0.48; a Ga_{0.47}In_{0.53}As third well layer 56 with a thickness of d₅ (d₅=a₃×d_{w0}) and a Ga composition ratio of 0.47; and an Al_{0.4}In_{0.53}As terminal barrier layer 57 with a thickness of 2.0 nm and an Al composition ratio of 0.48.

The Ga_{0.47}In_{0.53}As first well layer 52 and the Al_{0.4}In_{0.53}As first barrier layer 53 constitute a first pair of stacked layers 52a, and the Ga_{0.47}In_{0.53}As second well layer 54 and the Al_{0.4}In_{0.53}As second barrier layer 55 constitute a second pair of stacked layers 54a, respectively.

For the convenience of calculation in the method for designing a quantum cascade laser device, a Ga_{0.47}In_{0.53}As dummy well layer 101c and a Ga_{0.47}In_{0.53}As dummy well layer 101d, each having a Ga composition ratio of 0.47, are virtually provided on both end sides of the active region 130.

Since a laser oscillation wavelength is assumed to be about 9 μm in the active region 130, the thickness d_{w0} of the reference well layer and the thickness d_{b0} of the reference barrier layer are set to 8.0 nm and 1.0 nm, respectively. The thicknesses of the AlInAs starting barrier layer 51 and the AlInAs terminal barrier layer 57 are set to both 2.0 nm. However, the thicknesses of the AlInAs starting barrier layer and the AlInAs terminal barrier layer are not limited to such layer thickness, as long as the layer thickness thereof is sufficient to allow electron tunneling.

In a case where a₁=1.0, a₂=1.0, and a₃=1.0, which are examples of the thicknesses of the layers constituting the active region 130, that is, in a case where the thickness of each well layers is equal to the layer thickness d_{w0} of the reference well layer and the thickness of each barrier layer except for the AlInAs starting barrier layer 51 and the AlInAs terminal barrier layer 57 is equal to the thickness d_{b0} of the reference barrier layer, by applying the method for designing a quantum cascade laser device according to Embodiment 1, each quantum level (each eigenvalue) and each wave function (each eigenfunction) are calculated by solving the Schrödinger equation represented by Equation (6).

According to the above-described setting, the thicknesses of the layers constituting the active region 130 are as follows: the thickness d₁ of the GaInAs first well layer 52 is 8.0 nm; the thickness d₂ of the AlInAs first barrier layer 53 is 1.0 nm; the thickness d₃ of the GaInAs second well layer 54 is 8.0 nm; the thickness d₄ of the AlInAs second barrier layer 55 is 1.0 nm; and the thickness d₅ of the GaInAs third well layer 56 is 8.0 nm.

FIG. 21 is a graph showing the electron energy dependence of the electron transmissivity T in the structure of the active region 130 shown in FIG. 20. As shown in FIG. 21, it is found that there are six local maximum values E₁, E₂, E₃, E₄, E₅, and E₆ in the electron transmissivity T.

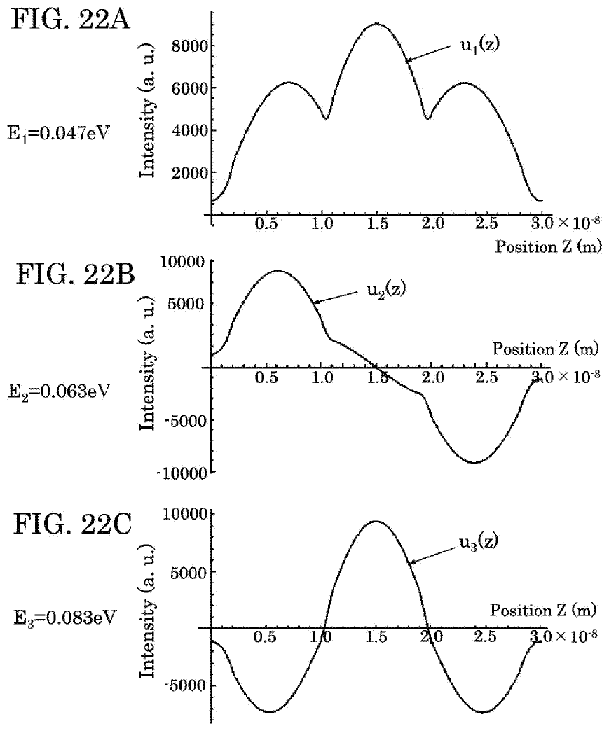

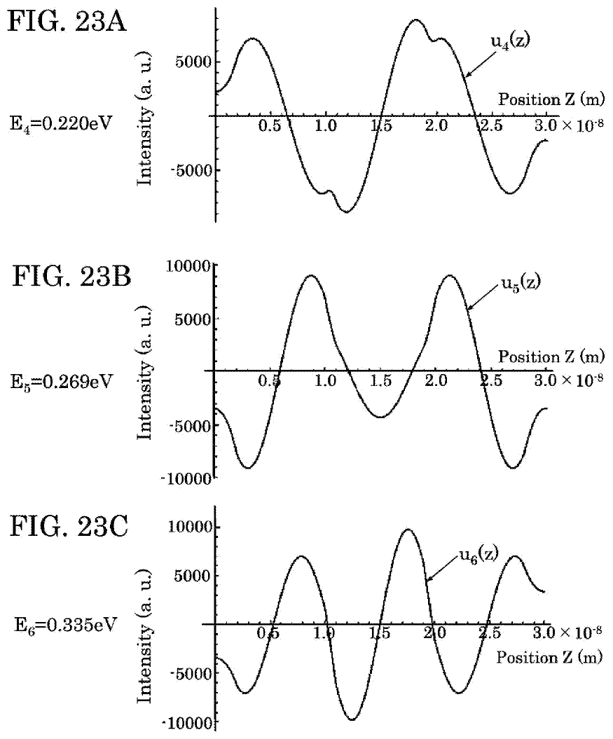

With respect to the active region 130, each quantum level (each eigenvalue) and each wave function (each eigenfunction) obtained by solving the Schrödinger equation represented by Equation (6) with each local maximum value in energy obtained from FIG. 21 as initial values are shown in FIGS. 22A-22C and 23A-23C, respectively.

FIG. 22A represents the wave function of the first quantum level E₁(E₁=0.047 eV), FIG. 22B represents the wave function of the second quantum level E₂ (E₂=0.063 eV), and FIG. 22C represents the wave function of the third quantum level E₃ (E₃=0.083 eV), respectively. FIG. 23A represents the wave function of the fourth quantum level E₄ (E₄=0.220 eV), FIG. 23B represents the wave function of the fifth quantum level E₅(E₅=0.269 eV), and FIG. 23C represents the wave function of the sixth quantum level E₆ (E₆=0.335 eV), respectively.

If the transition for laser oscillation occurs between the fourth quantum level E₄ (E₄=0.220 eV) and the third quantum level E₃ (E₃=0.083 eV), the energy difference between the fourth quantum level E₄ and the third quantum level E₃ is 0.137 eV, and thus the transition wavelength is 9.1 μm.

As described above, when the number of eigenvalues and the approximate values of the eigenvalues are calculated in advance and the approximate values are used as initial values, the Schrödinger equation can be easily solved, and thus the corresponding wave functions can also be easily obtained.

Furthermore, the well layer and the barrier layer adjacent to the well layer of the active region 130 are regarded as a pair of stacked layers, and the thicknesses of the well layer and the barrier layer of the same pair of stacked layers are set by multiplying the thickness of the reference well layer and the thickness of the reference barrier layer by the same coefficient, which is a positive real number, respectively. Therefore, the number of parameters for determining the layer thicknesses can be reduced, which facilitates setting thicknesses of well layers and barrier layers when designing an active region of a quantum cascade laser device.

### Modification 1 of Embodiment 3

The coefficients a₁, a₂, and a₃, which are positive real numbers, can take arbitrary values. The active region 130a of the quantum cascade laser device according to Modification 1 of Embodiment 3 has a₁=1.0, a_{2=0.8}, and a₃=0.8. That is, the thickness d₁ of the GaInAs first well layer 52 is the same thickness of the reference well layer and the thickness d₂ of the GaInAs first barrier layer 53 is the same thickness of the reference barrier layer, and the thickness of each well layer except for the GaInAs first well layer 52 is the thickness of the reference well layer multiplied by 0.8, and the thickness of each barrier layer except for the AlInAs starting barrier layer 51, the GaInAs first barrier layer 53 and the AlInAs terminal barrier layer 57 is the thickness of the reference barrier layer multiplied by 0.8.

According to the above-described setting, the thicknesses of the layers constituting the active region 130a are as follows: the thickness d₁ of the GaInAs first well layer 52 is 8.0 nm; the thickness d₂ of the AlInAs first barrier layer 53 is 1.0 nm; the thickness d₃ of the GaInAs second well layer 54 is 6.4 nm; the thickness d₄ of the AlInAs second barrier layer 55 is 0.8 nm; and the thickness d₅ of the GaInAs third well layer 56 is 6.4 nm.

For the active region 130a of the quantum cascade laser device according to Modification 1 of Embodiment 3, by applying the method for designing a quantum cascade laser device according to Embodiment 1, each quantum level (each eigenvalue) and each wave function (each eigenfunction) are calculated by solving the Schrödinger equation represented by Equation (6).

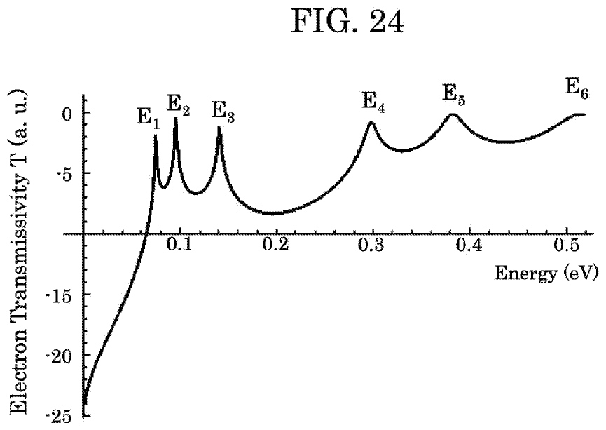

FIG. 24 is a graph showing the electron energy dependence of the electron transmissivity T in the structure of the active region 130a. As shown in FIG. 24, it is found that there are six local maximum values E₁, E₂, E₃, E₄, E₅, and E₆ in the electron transmissivity T.

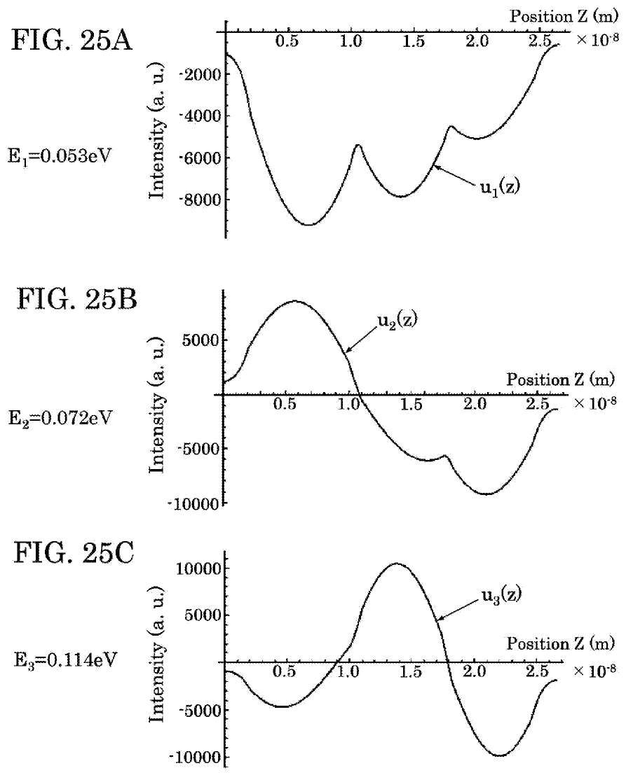

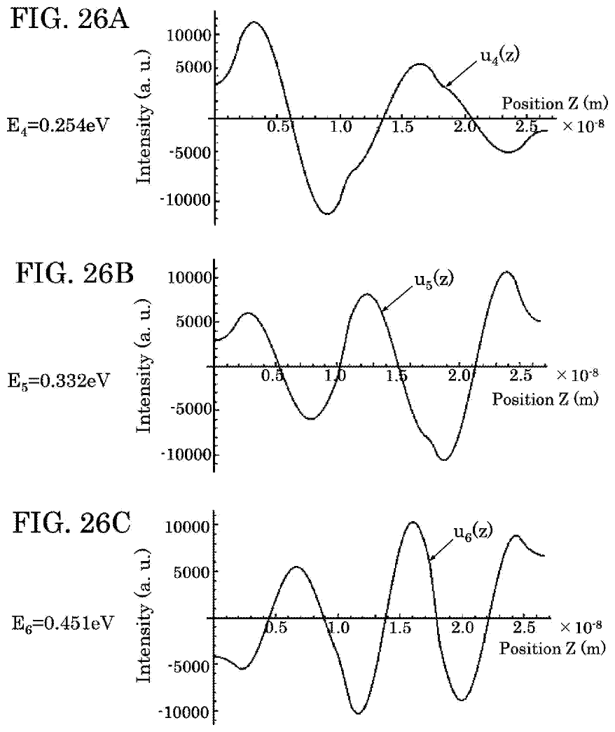

With respect to the active region 130a, each quantum level (each eigenvalue) and each wave function (each eigenfunction) obtained by solving the Schrödinger equation represented by Equation (6) with each local maximum value in energy obtained from FIG. 24 as initial values are shown in FIGS. 25A-25C and 26A-26C, respectively.

FIG. 25A represents the wave function of the first quantum level E₁(E₁=0.053 eV), FIG. 25B represents the wave function of the second quantum level E₂ (E₂=0.072 eV), and FIG. 25C represents the wave function of the third quantum level E₃ (E₃=0.114 eV), respectively. FIG. 26A represents the wave function of the fourth quantum level E₄ (E₄=0.254 eV), FIG. 26B represents the wave function of the fifth quantum level E₅(E₅=0.332 eV), and FIG. 26C represents the wave function of the sixth quantum level E₆ (E₆=0.451 eV), respectively.

If the transition for laser oscillation occurs between the fourth quantum level E₄ (E₄=0.254 eV) and the third quantum level E₃ (E₃=0.114 eV), the energy difference between the fourth quantum level E₄ and the third quantum level E₃ is 0.140 eV, and thus the transition wavelength is 8.8 μm.

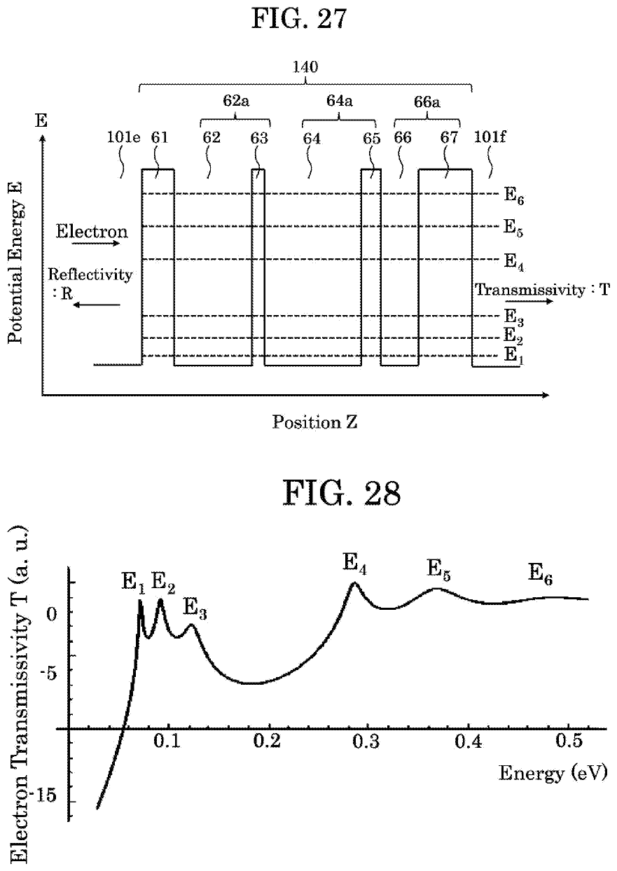

Modification 2 of Embodiment 3 FIG. 27 is a diagram showing a conduction band structure of an active region 140 of a quantum cascade laser device according to Modification 2 of Embodiment 3 when no bias is applied. The quantum cascade laser device according to Modification 2 of Embodiment 3 is characterized in that the terminal barrier layer is also treated as a part of a pair of stacked layers.

The active region 140 includes: an Al_{0.48}In_{0.52}As starting barrier layer 61 with a thickness of 2.0 nm and an Al composition ratio of 0.48; a Ga_{0.47}In_{0.53}As first well layer 62 with a thickness of d₁ (d₁=a₁×d_{w0}) and a Ga composition ratio of 0.47; an Al_{0.48}In_{0.53}As first barrier layer 63 with a thickness of d₂ (d₂=a₁×d_{b0}) and an Al composition ratio of 0.48; a Ga_{0.47}In_{0.53}As second well layer 64 with a thickness of d₃ (d₃=a₂×d_{w0}) and a Ga composition ratio of 0.47; an Al_{0.48}In_{0.53}As second barrier layer 65 with a thickness of d₄ (d₄=a₂×d_{b0}) and an Al composition ratio of 0.48; a Ga_{0.47}In_{0.53}As third well layer 66 with a thickness of d₅ (d₅=a₃×d_{w0}) and a Ga composition ratio of 0.47; and an Al_{0.4}In_{0.53}As terminal barrier layer 67 with a thickness of d₆ (d₆=a₃×d_{b0}) and an Al composition ratio of 0.48.

The Ga_{0.47}In_{0.53}As first well layer 62 and the Al_{0.4}In_{0.53}As first barrier layer 63 constitute a first pair of stacked layers 62a, the Ga_{0.47}In_{0.53}As second well layer 64 and the Al_{0.4}In_{0.53}As second barrier layer 65 constitute a second pair of stacked layers 64a, and the Ga_{0.47}In_{0.53}As third well layer 66 and the Al_{0.48}In_{0.53}As third barrier layer 67 constitute a third pair of stacked layers 66a.

For the convenience of calculation in the method for designing a quantum cascade laser device, a Ga_{0.47}In_{0.53}As dummy well layer 101e and a Ga_{0.47}In_{0.53}As dummy well layer 101f, each having a Ga composition ratio of 0.47, are virtually provided on both end sides of the active region 140.

Since a laser oscillation wavelength is assumed to be about 9 μm in the active region 140, the thickness d_{w0} of the reference well layer and the thickness d_{b0} of the reference barrier layer are set to 8.0 nm and 1.0 nm, respectively. The thickness of the AlInAs starting barrier layer 61 is set to 2.0 nm. However, the thickness of the AlInAs starting barrier layer 61 is not limited to such layer thickness, as long as the layer thickness thereof is sufficient to allow electron tunneling.

In a case where a₁=1.0, a₂=0.9, and a₃=0.8, which are examples of the thicknesses of the layers constituting the active region 140, by applying the method for designing a quantum cascade laser device according to Embodiment 1, each quantum level (each eigenvalue) and each wave function (each eigenfunction) are calculated by solving the Schrödinger equation represented by Equation (6).

According to the above-described setting, the thicknesses of the layers constituting the active region 140 are as follows: the thickness d₁ of the GaInAs first well layer 62 is 8.0 nm; the thickness d₂ of the AlInAs first barrier layer 63 is 1.0 nm; the thickness d₃ of the GaInAs second well layer 64 is 7.2 nm; the thickness d₄ of the AlInAs second barrier layer 65 is 0.9 nm; and the thickness d₅ of the GaInAs third well layer 66 is 6.4 nm; and the thickness d₄ of the AlInAs third barrier layer 67 is 0.8 nm.

FIG. 28 is a graph showing the electron energy dependence of the electron transmissivity T in the structure of the active region 140 shown in FIG. 27. As shown in FIG. 28, it is found that there are six local maximum values E₁, E₂, E₃, E₄, E₅, and E₆ in the electron transmissivity T.

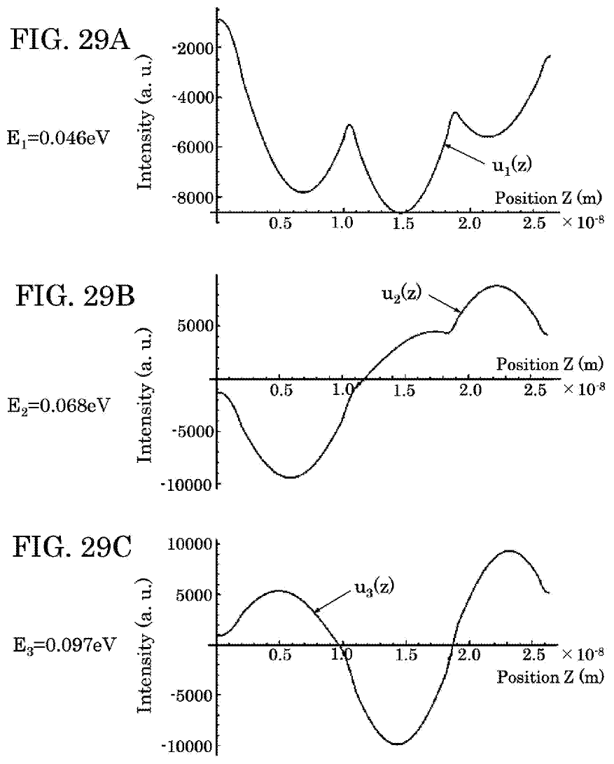

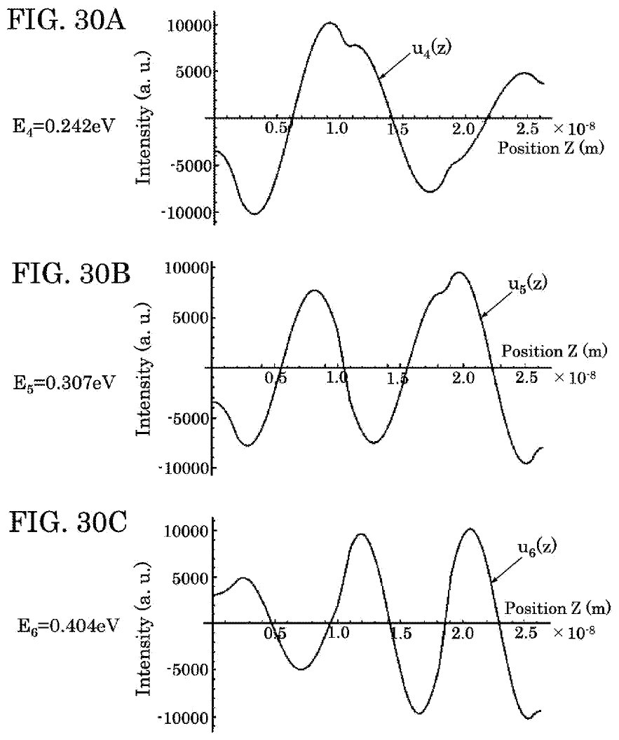

With respect to the active region 140, each quantum level (each eigenvalue) and each wave function (each eigenfunction) obtained by solving the Schrödinger equation represented by Equation (6) with each local maximum value in energy obtained from FIG. 28 as initial values are shown in FIGS. 29A-29C and 30A-30C, respectively.

FIG. 29A represents the wave function of the first quantum level E₁ (E₁=0.046 eV), FIG. 29B represents the wave function of the second quantum level E₂ (E₂=0.068 eV), and FIG. 29C represents the wave function of the third quantum level E₃ (E₃=0.097 eV), respectively. FIG. 30A represents the wave function of the fourth quantum level E₄ (E₄=0.242 eV), FIG. 30B represents the wave function of the fifth quantum level E₅(E₅=0.307 eV), and FIG. 30C represents the wave function of the sixth quantum level E₆ (E₆=0.404 eV), respectively.

If the transition for laser oscillation occurs between the fourth quantum level E₄ (E₄=0.242 eV) and the third quantum level E₃ (E₃=0.097 eV), the energy difference between the fourth quantum level E₄ and the third quantum level E₃ is 0.145 eV, and thus the transition wavelength is 8.6 μm.

As described above, when the number of eigenvalues and the approximate values of the eigenvalues are calculated in advance and the approximate values are used as initial values, the Schrödinger equation can be easily solved, and thus the corresponding wave functions can also be easily obtained.

Furthermore, the well layer and the barrier layer adjacent to the well layer of the active region 140 are regarded as a pair of stacked layers, and the thicknesses of the well layer and the barrier layer of the same pair of stacked layers are set by multiplying the thickness of the reference well layer and the thickness of the reference barrier layer by the same coefficient, which is a positive real number, respectively. Therefore, the number of parameters for determining the layer thicknesses can be reduced, which facilitates setting thicknesses of well layers and barrier layers when designing an active region of a quantum cascade laser device.

### Modification 3 of Embodiment 3

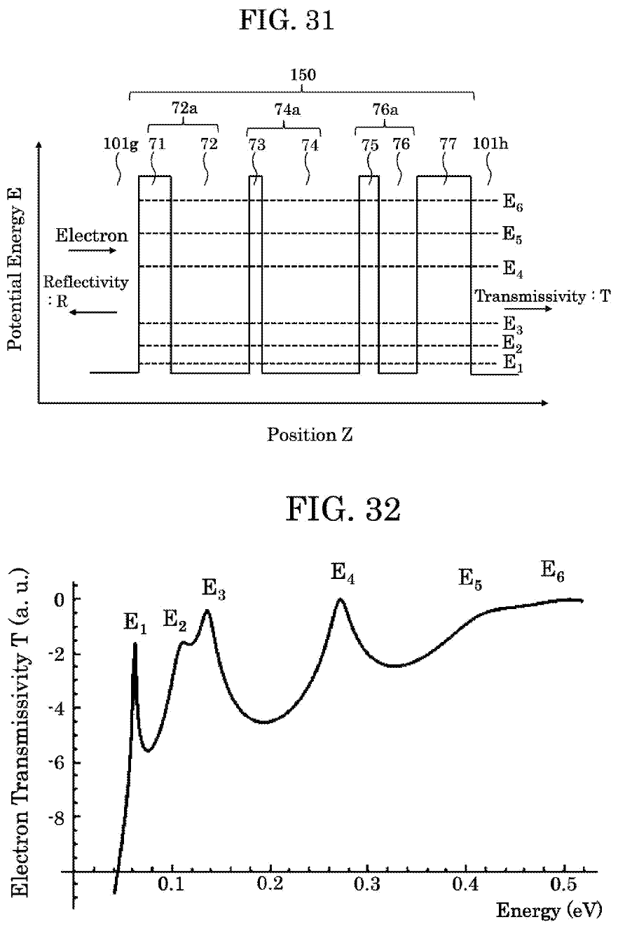

FIG. 31 is a diagram showing a conduction band structure of an active region 150 of a quantum cascade laser device according to Modification 3 of Embodiment 3 when no bias is applied.

The active region 150 includes: an Al_{0.48}In_{0.52}As starting barrier layer 71 with a thickness of d₁ (d₁=a₁×d_{b0}) and an Al composition ratio of 0.48; a Ga_{0.47}In_{0.53}As first well layer 72 with a thickness of d₂ (d₂=a₁×d_{w0}) and a Ga composition ratio of 0.47; an Al_{0.48}In_{0.53}As first barrier layer 73 with a thickness of d₃ (d₃=a₂×d_{b0}) and an Al composition ratio of 0.48; a Ga_{0.47}In_{0.53}As second well layer 74 with a thickness of d₄ (d₄=a₂×d_{w0}) and a Ga composition ratio of 0.47; an Al_{0.48}In_{0.53}As second barrier layer 75 with a thickness of d₅ (d₅=a₃×d_{b0}) and an Al composition ratio of 0.48; a Ga_{0.47}In_{0.53}As third well layer 76 with a thickness of d₆ (d₆=a₃×d_{w0}) and a Ga composition ratio of 0.47; and an Al_{0.48}In_{0.53}As terminal barrier layer 77 with a thickness of d₇ (d₇=a₄×d_{b0}) and an Al composition ratio of 0.48.

The Al_{0.48}In_{0.53}As first barrier layer 71 and the Ga_{0.47}In_{0.53}As first well layer 72 constitute a first pair of stacked layers 72a, the Al_{0.48}In_{0.53}As second barrier layer 73 and the Ga_{0.47}In_{0.53}As second well layer 74 constitute a second pair of stacked layers 74a, and the Al_{0.48}In_{0.53}As third barrier layer 75 and the Ga_{0.47}In_{0.53}As third well layer 76 and constitute a third pair of stacked layers 76a.

For the convenience of calculation in the method for designing a quantum cascade laser device, a Ga_{0.47}In_{0.53}As dummy well layer 101g and a Ga_{0.47}In_{0.53}As dummy well layer 101h, each having a Ga composition ratio of 0.47, are virtually provided on both end sides of the active region 150.

Since a laser oscillation wavelength is assumed to be about 9 μm in the active region 150, the thickness d_{w0} of the reference well layer and the thickness d_{b0} of the reference barrier layer are set to 8.0 nm and 1.0 nm, respectively.

In a case where a₁=0.8, a_{2=1.1}, a₃=0.7, and a₄=1.2, which are examples of the thicknesses of the layers constituting the active region 150, by applying the method for designing a quantum cascade laser device according to Embodiment 1, each quantum level (each eigenvalue) and each wave function (each eigenfunction) are calculated by solving the Schrödinger equation represented by Equation (6).

According to the above-described setting, the thicknesses of the layers constituting the active region 150 are as follows: the thickness d₁ of the AlInAs first barrier layer 71 is 0.8 nm; the thickness d₂ of the GaInAs first well layer 72 is 6.4 nm; the thickness d₃ of the AlInAs second barrier layer 73 is 1.1 nm; the thickness d₄ of the GaInAs second well layer 74 is 8.8 nm; the thickness d₅ of the AlInAs third barrier layer 75 is 0.7 nm; the thickness d₆ of the GaInAs third well layer 76 is 5.6 nm; and the thickness d₇ of the AlInAs terminal barrier layer 77 is 1.2 nm.

FIG. 32 is a graph showing the electron energy dependence of the electron transmissivity T in the structure of the active region 150 shown in FIG. 31. As shown in FIG. 32, it is found that there are six local maximum values E₁, E₂, E₃, E₄, E₅, and E₆ in the electron transmissivity T.

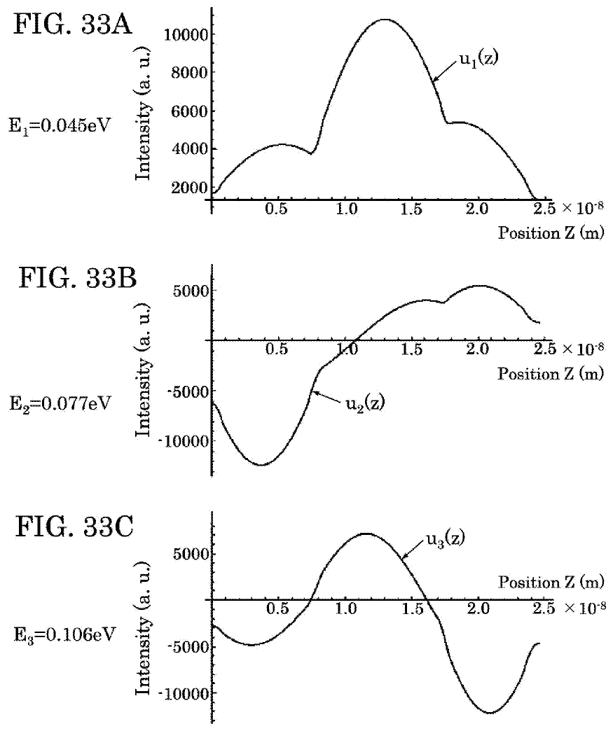

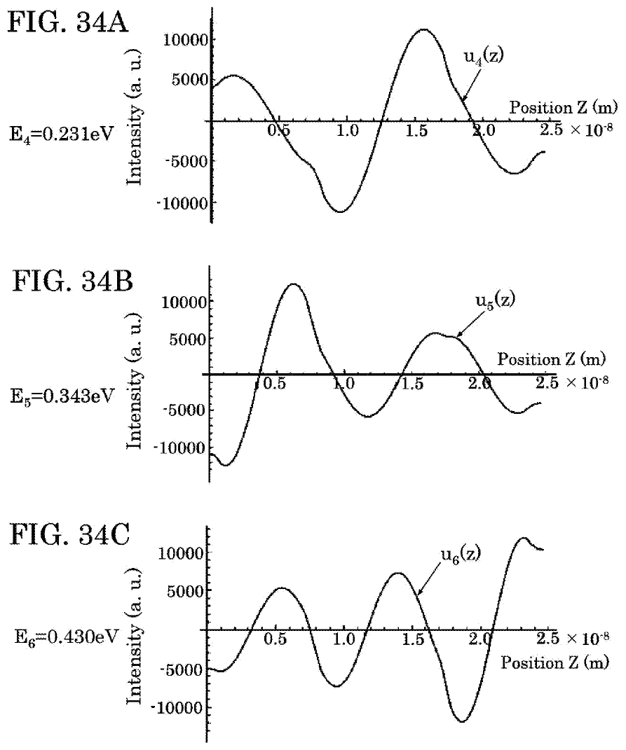

With respect to the active region 150, each quantum level (each eigenvalue) and each wave function (each eigenfunction) obtained by solving the Schrödinger equation represented by Equation (6) with each local maximum value in energy obtained from FIG. 32 as initial values are shown in FIGS. 33A-33C and 34A-34C, respectively.

FIG. 33A represents the wave function of the first quantum level E₁ (E₁=0.045 eV), FIG. 33B represents the wave function of the second quantum level E₂ (E₂=0.077 eV), and FIG. 33C represents the wave function of the third quantum level E₃ (E₃=0.106 eV), respectively. FIG. 34A represents the wave function of the fourth quantum level E₄ (E₄=0.231 eV), FIG. 34B represents the wave function of the fifth quantum level E₅ (E₅=0.343 eV), and FIG. 34C represents the wave function of the sixth quantum level E₆ (E₆=0.430 eV), respectively.

If the transition for laser oscillation occurs between the fourth quantum level E₄ (E₄=0.231 eV) and the third quantum level E₃ (E₃=0.106 eV), the energy difference between the fourth quantum level E₄ and the third quantum level E₃ is 0.125 eV, and thus the transition wavelength is 9.9 μm.

As described above, when the number of eigenvalues and the approximate values of the eigenvalues are calculated in advance and the approximate values are used as initial values, the Schrödinger equation can be easily solved, and thus the corresponding wave functions can also be easily obtained.

Furthermore, the well layer and the barrier layer adjacent to the well layer of the active region 150 are regarded as a pair of stacked layers and the thicknesses of the well layer and the barrier layer of the same pair of stacked layers are set by multiplying the thickness of the reference well layer and the thickness of the reference barrier layer by the same coefficient, which is a positive real number, respectively. Therefore, the number of parameters for determining the layer thicknesses can be reduced, which facilitates setting thicknesses of well layers and barrier layers when designing an active region of a quantum cascade laser device.

In the above description, the number of barrier layers and the number of well layers are each three or four. However, as described below, the structure of the active region can be designed in the same manner even when the number of barrier layers and the number of well layers are each five or more.

It is assumed that at least n barrier layers and n well layers are alternately stacked in the active region. In this case, a pair of the well layer and the barrier layer adjacent to the well layer is regarded as a pair of stacked layers, and n pairs of stacked layers from a first pair of stacked layers to an n-th pair of stacked layers are included in the active region. The thickness d_{b0} of the reference barrier layer through which electrons can tunnel and the thickness d_{w0} of the reference well layer having a predetermined thickness thicker than the thickness of the reference barrier layer can be set, and the thickness of the well layer of a k-th (1≤k≤n) pair of stacked layers can be set to aₖ×d_{w0} and the thickness of the barrier layer of the k-th pair of stacked layers can be set to aₖ×d_{b0} for the n pairs of stacked layers.

### Effects of Embodiment 3

As described above, the method for designing a quantum cascade laser device according to Embodiment 3, since the well layer and the barrier layer adjacent to the well layer are regarded as a pair of stacked layers, and the thicknesses of the well layer and the thickness of the barrier layer of the same pair of stacked layers are set by multiplying the thickness of the reference well layer and the thickness of the reference barrier layer by the same coefficient, which is a positive real number, respectively, the number of parameters for determining the layer thicknesses can be reduced, and thus the thicknesses of the well layers and the barrier layers can be easily set, thus providing an effect that a quantum cascade laser device in which a laser oscillation wavelength is easily designed can be obtained.

Furthermore, since the thickness of each layer of the active region constituting the quantum cascade laser device according to Embodiment 3 is determined by applying the method for designing a quantum cascade laser device according to Embodiment 1, it is possible to easily estimate the transition wavelength with respect to the structure of the active region, thus providing an effect that it is possible to easily design a quantum cascade laser device.

In Embodiment 1 and Embodiment 3, the case of no bias is shown as an example, but in the case of bias, the quantum levels in the case of no bias can be used as initial values to solve the Schrödinger equation.

Furthermore, in Embodiment 2 and Embodiment 3, the case of no bias is shown as an example, but in the case of bias, the well layer and the barrier layer adjacent to the well layer can be treated as a pair of stacked layers in the same way.

In Embodiment 1 to Embodiment 3, the quantum cascade laser device grown on the InP substrate is taken as an example, and the well layer is made of a GaInAs layer and the barrier layer is made of an AlInAs layer. However, it is not limited to such semiconductor materials. For example, a quantum cascade laser device may be configured such that well layers are made of GaAs and barrier layers are made of AlGaAs on a GaAs substrate. Furthermore, a quantum cascade laser device may be configured such that well layers are made of InGaN and barrier layers are made of AlGaN on a GaN substrate. Moreover, for example, the same elemental composition may be used as semiconductor layers, but only the composition ratio may be changed, such that well layers are made of Al_{0.1}Ga_{0.9}As and barrier layers are made of Al_{0.5}Ga_{0.5}As.

In Embodiment 2 and Embodiment 3, the coefficients an (n=1, 2, . . . , n) are positive real numbers to represent the effect of a pair of stacked layers, but the coefficients aₙ are not limited to positive real numbers, and the coefficients aₙ can take any values.

In Embodiment 2 and Embodiment 3, specific examples of the thicknesses of the reference well layer and the reference barrier layer are described, but the layer thickness values are not limited to the above-described values. In short, the thickness of the reference barrier layer may be a thickness through which electrons can tunnel, and the thickness of the reference well layer may be thicker than the thickness of the reference barrier layer.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 back-surface-side n-type electrode
2 n-type InP substrate
3 n-type InP buffer layer
4 n-type GaInAs first optical confinement layer
5 core region
6 n-type GaInAs second optical confinement layer
7 n-type InP cladding layer
8 n-type GaInAs contact layer
9 front-surface-side n-type electrode
10, 26, 31 41, 51, 61 Al_{0.48}In_{0.52}As starting barrier layer
11, 32, 42, 52, 62, 72 Ga_{0.47}In_{0.53}As first well layer
12, 33, 43, 53, 63, 71 Al_{0.48}In_{0.52}As first barrier layer
13, 34, 44, 54, 64, 74 Ga_{0.47}In_{0.53}As second well layer
14, 35, 45, 55, 65, 73 Al_{0.48}In_{0.52}As second barrier layer
15, 36, 46, 56, 66, 76 Ga_{0.47}In_{0.53}As third well layer
16, 39, 47, 57, 77 Al_{0.48}In_{0.52}As terminal barrier layer
17 Ga_{0.47}In_{0.53}As injector region first well layer
18 Al_{0.48}In_{0.52}As injector region first barrier layer
19 Ga_{0.47}In_{0.53}As injector region second well layer
20 Al_{0.48}In_{0.52}As injector region second barrier layer
21 Ga_{0.47}In_{0.53}As injector region third well layer
22 Al_{0.48}In_{0.52}As injector region third barrier layer
23 Ga_{0.47}In_{0.53}As injector region fourth well layer
24 Al_{0.48}In_{0.52}As injector region fourth barrier layer
25 Ga_{0.47}In_{0.53}As injector region fifth well layer
32a, 42a, 52a, 62a first pair of stacked layers
34a, 44a, 54a, 64a second pair of stacked layers
36a, 66a, 76a third pair of stacked layers
37, 67, 75 Al_{0.48}In_{0.52}As third barrier layer
38 Ga_{0.47}In_{0.53}As fourth well layer
100, 110, 120, 120a, 130, 130a, 140, 150 active region
101a, 101b, 101c, 101d, 101e, 101f, 101g, 101h Ga_{0.47}In_{0.53}As dummy well layer
200 injector region
300 stage
300a first stage
500 quantum cascade laser device

1.-10. (canceled)

11. A method for manufacturing a quantum cascade laser device having an active region with at least n layers of barrier layers and n layers of well layers alternately stacked, the method comprising the steps of:
setting the number of the barrier layers and the number of the well layers to be at least n layers each;
setting n pairs of stacked layers from a first pair of stacked layers to an n-th pair of stacked layers in the active region, each pair of stacked layers being a pair of the well layer and the barrier layer adjacent to the well layer;
setting an electron-tunnelable thickness of a reference barrier layer as d_{b0} and a thickness of a reference well layer having a thickness thicker than the thickness of the reference barrier layer as d_{w0}, respectively;
setting n coefficients from a coefficient a₁ to a coefficient aₙ, each of the n coefficients being a positive real number;
setting the thickness of the well layer and the thickness of the barrier layer of the k-th (1≤k≤n) pair of stacked layers as aₖ×d_{w0} and aₖ×d_{b0} respectively, with respect to the n pairs of stacked layers;
virtually injecting electrons having an energy value from zero to an energy value of a conduction band edge of the well layer into a starting barrier layer, the starting barrier layer being a barrier layer provided on one end side and a terminal barrier layer being a barrier layer provided on the other end side;
calculating energy dependence of transmissivity of the electrons transmitted from the terminal barrier layer;
calculating energy values of local maximum values where the transmissivity of the electrons is locally maximized and the number of the local maximum values;
calculating eigenvalues and eigenfunctions of a Schrödinger equation by solving the Schrödinger equation for each local maximum value by using each energy value of the local maximum values as an initial value; and
setting a laser oscillation wavelength on the basis of the eigenvalues calculated for each of the local maximum values.

12. A quantum cascade laser device comprising:
a substrate;
a first optical confinement layer formed above the substrate;
a core region formed on the first optical confinement layer and including a plurality of stages;
a second optical confinement layer formed on the core region; and
a cladding layer formed on the second optical confinement layer, wherein
the stage includes:
an active region with at least n layers of barrier layers and n layers of well layers alternately stacked, a barrier layer provided on one end side of the active region being a starting barrier layer, and a barrier layer provided on the other end side of the active region being a terminal barrier layer; and
an injector region that injects electrons into the active region, wherein
energy dependence of transmissivity of the electrons transmitted from the terminal barrier layer is calculated by virtually injecting the electrons having an energy value from zero to an energy value of a conduction band edge of the well layer into the starting barrier layer,
energy values of local maximum values where the transmissivity of the electrons is locally maximized, and the number of the local maximum values are calculated,
eigenvalues and eigenfunctions of a Schrödinger equation are calculated by solving the Schrödinger equation for each local maximum value by using each energy value of the local maximum values as an initial value, and
the quantum cascade laser device has a laser oscillation wavelength on the basis of the eigenvalue calculated for each of the local maximum values.

13. A quantum cascade laser device according to claim 12, wherein
the active region includes n pairs of stacked layers from a first pair of stacked layers to an n-th pair of stacked layers, each pair of stacked layers being a pair of a well layer and a barrier layer adjacent to the well layer, wherein
using a predetermined electron-tunnelable thickness d_{b0} of a reference barrier layer, a predetermined thickness d_{w0} of a reference well layer having a thickness thicker than the thickness of the reference barrier layer, and n coefficients from a coefficient a₁ to a coefficient aₙ that are predetermined positive real numbers, a thickness of the well layer and a thickness of the barrier layer of the k-th (1≤k≤n) pair of stacked layers are respectively set as aₖ×d_{w0} and aₖ×d_{b0} with respect to the n pair of stacked layers.

14. The quantum cascade laser device according to claim 12, wherein
the number of n layers is three or four.

15. A quantum cascade laser device comprising:
a substrate;
a first optical confinement layer formed above the substrate;
a core region formed on the first optical confinement layer and including a plurality of stages;
a second optical confinement layer formed on the core region; and
a cladding layer formed on the second optical confinement layer, wherein
the stage includes:
an active region with at least n layers of barrier layers and n layers of well layers alternately stacked, a barrier layer provided on one end side of the active region being a starting barrier layer, and a barrier layer provided on the other end side of the active region being a terminal barrier layer; and
an injector region that injects electrons into the active region, wherein
the active region includes n pairs of stacked layers from a first pair of stacked layers to an n-th pair of stacked layers, each pair of stacked layers being a pair of a well layer and a barrier layer adjacent to the well layer,
using a predetermined electron-tunnelable thickness d_{b0} of a reference barrier layer, a predetermined thickness d_{w0} of a reference well layer having a thickness thicker than the thickness of the reference barrier layer, and n coefficients from a coefficient a₁ to a coefficient aₙ that are predetermined positive real numbers, a thickness of the well layer and a thickness of the barrier layer of the k-th (1≤k≤n) pair of stacked layers are respectively set as aₖ×d_{w0} and aₖ×d_{b0} with respect to the n pair of stacked layers, and
at least one of the n coefficients aₙ is a numerical value different from the other coefficients.

16. The quantum cascade laser device according to claim 15, wherein
in a case where n is 3, the coefficients aₙ are a₁=1.0, a₂=0.8, a₃=0.8, or a₁=1.0, a₂=0.9, a₃=0.8.

17. The quantum cascade laser device according to claim 15, wherein
in a case where n is 4, the coefficients aₙ are a₁=1.0, a₂=0.9, a₃=0.9, a₄=0.9, or a₁=0.8, a₂=1.1, a₃=0.7, a₄=1.2.

18. The quantum cascade laser device according to claim 12, wherein
the well layer is made of a GaInAs layer, and the barrier layer is made of an AlInAs layer.

19. The quantum cascade laser device according to claim 12, wherein
the core region is composed of 30 or more and 40 or less stages.
